(19) United States
(12) Patent Application Publication
(10) Pub. No.: US 2024/0234665 A1
(43) Pub. Date: Jul. 11, 2024

(54) DISPLAY DEVICE AND METHOD OF MANUFACTURING THE SAME

(71) Applicant: Samsung Display Co., Ltd., Yongin-si (KR)

(72) Inventors: SANG-CHUL BYUN, Yongin-si (KR); KYU-HO JUNG, Yongin-si (KR); TAEOH KIM, Yongin-si (KR); SOO YEON HAN, Yongin-si (KR)

(21) Appl. No.: 18/503,054

(22) Filed: Nov. 6, 2023

(30) Foreign Application Priority Data
Jan. 6, 2023 (KR) 10-2023-0002447

(51) Int. Cl. H01L 33/62; H01L 25/075; H01L 25/16; H01L 27/15; H01L 33/44; H01L 33/50; H01L 33/58

(52) U.S. Cl. CPC H01L 33/62; H01L 25/0753; H01L 25/167; H01L 27/156; H01L 33/44; H01L 33/505; H01L 33/58; H01L 2933/0025; H01L 2933/0058; H01L 2933/0066

(57) ABSTRACT

A display device includes: a substrate including a display area and a non-display area adjacent to the display area; a light emitting element layer in the display area on the substrate and including a plurality of light emitting elements; a pad part in the non-display area on the substrate and spaced apart from the light emitting element layer; a lens layer on the light emitting element layer and including a plurality of micro lenses; and a coating layer on the lens layer, covering a side surface of the light emitting element layer and contacting the substrate.

### CROSS-REFERENCE TO RELATED APPLICATION(S)

The present application claims priority to and the benefit of Korean Patent Application No. 10-2023-0002447 filed on Jan. 6, 2023, in the Korean Intellectual Property Office (KIPO), the entire disclosure of which is incorporated herein by reference.

### BACKGROUND

### 1. Field

Aspects of some embodiments relate to a display device.

### 2. Description of the Related Art

A display device is a device that displays images to provide visual or graphical representations of information to a user. Among display devices, an organic light emitting display device has recently been attracting attention.

Recently, a head-mounted display (HMD) including a display device has been developed. The head-mounted display is a glasses-type or wearable monitor device that may be capable of providing a virtual reality (VR) or augmented reality (AR) environment or experience, that is worn in a form of glasses, a helmet, or the like and focuses on a distance close to the user's eyes. The head-mounted display may display images on the display device to the user's eyes through a lens.

The above information disclosed in this Background section is only for enhancement of understanding of the background and therefore the information discussed in this Background section does not necessarily constitute prior art.

### SUMMARY

Aspects of some embodiments relate to a display device. For example, aspects of some embodiments relate to a micro display device and a method of manufacturing the same.

Aspects of some embodiments include a display device with relatively improved process efficiency.

Aspects of some embodiments include a method of manufacturing the display device.

A display device according to some embodiments of the present disclosure includes a substrate including a display area and a non-display area adjacent to the display area, a light emitting element layer in the display area on the substrate and including a plurality of light emitting elements, a pad part in the non-display area on the substrate and spaced apart from the light emitting element layer, a lens layer on the light emitting element layer and including a plurality of micro lenses, and a coating layer on the lens layer, covering a side surface of the light emitting element layer and contacting the substrate.

According to some embodiments, the coating layer may include poly silsesquioxane or siloxane.

According to some embodiments, a thickness of the coating layer may be in a range of about 300 μm to about 600 μm.

According to some embodiments, the display device may further include a low refractive index layer between the lens layer and the coating layer.

According to some embodiments, the low refractive index layer may include fluorine or hollow silica.

According to some embodiments, a refractive index of the low refractive index layer may be smaller than a refractive index of the micro lenses, and a difference between the refractive index of the low refractive index layer and the refractive index of the micro lenses may be in a range of about 0.1 to about 0.5.

According to some embodiments, the substrate may include a base substrate defining a plurality of grooves and including a silicon wafer, and a plurality of pixel circuit parts respectively accommodated in the plurality of grooves.

According to some embodiments, the coating layer may include a sealing part covering the side surface of the light emitting element layer, contacting the substrate and defining an opening overlapping the lens layer, and a filling part on the lens layer, spaced apart from the substrate and filling the opening.

According to some embodiments, the display device may further include a polarization layer on the coating layer.

According to some embodiments, the display device may further include a color filter layer between the light emitting element layer and the lens layer.

A method of manufacturing a display device according to some embodiments of the present disclosure includes forming a light emitting element layer including a plurality of light emitting elements in a display area on a mother substrate, forming a pad part in a non-display area on the mother substrate, forming a lens layer including a plurality of micro lenses on the light emitting element layer, and forming a coating layer covering a side surface of the light emitting element layer and contacting the mother substrate on the lens layer.

According to some embodiments, the method may further include attaching a release film to the non-display area on the mother substrate to cover the pad part before the forming the coating layer.

According to some embodiments, the forming the coating layer may include forming a preliminary coating layer on the mother substrate to cover the lens layer and the release film, cutting the preliminary coating layer, removing the release film and the preliminary coating layer overlapping the release film, and simultaneously cutting the preliminary coating layer and the mother substrate.

According to some embodiments, in the cutting the preliminary coating layer, the preliminary coating layer may be cut along one side surface of the display area adjacent to the release film, and in the simultaneously cutting the preliminary coating layer and the mother substrate, the preliminary coating layer and the mother substrate may be simultaneously cut along another side surface of the display area.

According to some embodiments, the cutting the preliminary coating layer and the simultaneously cutting of the preliminary coating layer and the mother substrate may be performed using a laser.

According to some embodiments, the method may further include forming a low refractive index layer on the lens layer before the forming the coating layer.

According to some embodiments, the forming the coating layer may include forming a sealing part covering the side surface of the light emitting element layer, contacting the mother substrate and defining an opening overlapping the lens layer, and forming a filling part on the lens layer, spaced apart from the mother substrate and filling the opening.

According to some embodiments, the method may further include forming a preliminary polarization layer on the preliminary coating layer before the cutting the preliminary coating layer.

According to some embodiments, the cutting the preliminary coating layer may include forming a polarization layer by cutting the preliminary polarization layer.

According to some embodiments, the mother substrate may be formed of a silicon wafer.

In a display device according to some embodiments of the present disclosure, the display device may include a low refractive index layer and a coating layer on a display part. The coating layer may cover upper and side surfaces of the display part, and may contact the substrate. Accordingly, the display part may be effectively protected.

In addition, in a method of manufacturing the display device according to some embodiments of the present disclosure, a preliminary coating layer and a release film covering a pad part may be formed on a mother substrate. Because the preliminary coating layer and the mother substrate may be cut by a laser in a same process, an additional process for cutting the mother substrate may not be required.

Accordingly, a manufacturing process may be simplified and efficiency in the manufacturing process may be improved.

### BRIEF DESCRIPTION OF THE DRAWINGS

FIG. 1 is a plan view illustrating a display device according to some embodiments of the present disclosure.

FIG. 2 is an enlarged plan view of area A of FIG. 1 according to some embodiments of the present disclosure.

FIG. 3 is a cross-sectional view taken along the line I-I′ of FIG. 2 according to some embodiments of the present disclosure.

FIG. 4 is a cross-sectional view taken along the lines II-II′ and III-III′ of FIG. 1 according to some embodiments of the present disclosure.

FIG. 5 is a cross-sectional view taken along the lines IV-IV' and V-V′ of FIG. 1 according to some embodiments of the present disclosure.

FIG. 6 is a cross-sectional view illustrating another example of FIG. 5 according to some embodiments of the present disclosure.

FIGS. 7 to 25 are views illustrating a method of manufacturing a display device according to some embodiments of the present disclosure.

FIGS. 26, 27 and 28 are views illustrating a method of manufacturing a display device according to some embodiments of the present disclosure.

FIGS. 29 to 36 are views illustrating a method of manufacturing a display device according to some embodiments of the present disclosure.

### DETAILED DESCRIPTION

Hereinafter, aspects of some embodiments of the present disclosure will be described in more detail with reference to the accompanying drawings. The same reference numerals are used for the same components in the drawings, and redundant descriptions of the same components will be omitted.

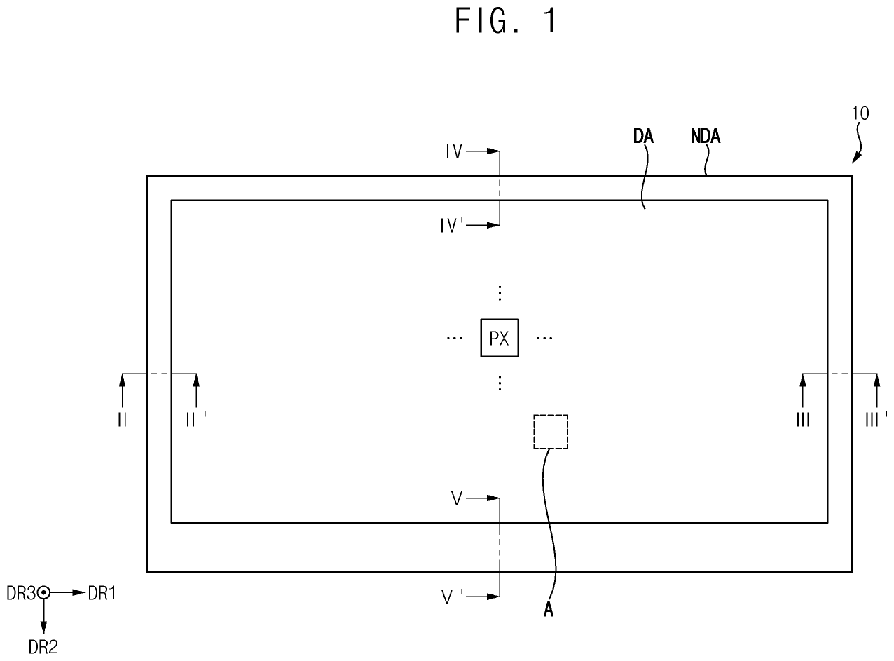

FIG. 1 is a plan view illustrating a display device according to some embodiments of the present disclosure.

Referring to FIG. 1, a display device 10 according to some embodiments of the present disclosure may include a display area DA and a non-display area NDA.

The display area DA may be an area that displays images. A planar shape of the display area DA may be a rectangular shape. However, the planar shape of the display area DA is not limited thereto, and the display area DA may have various planar shapes such as a circular shape, an elliptical shape, a polygonal shape, or the like.

The non-display area NDA may be an area where images are not displayed. The non-display area NDA may be arranged around (e.g., in a periphery of, or outside a footprint of) the display area DA in a plan view (e.g., when viewed from a direction perpendicular or normal with respect to a display surface of the display area DA). For example, the non-display area NDA may entirely surround the display area DA. According to some embodiments, drivers for displaying images at the display area DA may be located in the non-display area NDA.

A plurality of pixels PX may be repeatedly arranged along a first direction DR1 and a second direction DR2 crossing the first direction DR1 in a plan view in the display area DA. For example, the second direction DR2 may be perpendicular to the first direction DR1. Although FIG. 1 illustrates a single pixel PX, a person having ordinary skill in the art would recognize that the display area DA may include any suitable number of pixels PX according to the design of the display device 10.

Each of the pixels PX may be defined as a minimum light emitting unit capable of displaying light. In addition, signal lines such as a gate line and a data line may be located in the display area DA. The signal lines may be connected to each of the pixels PX. Each of the pixels PX may receive a gate signal, a data signal, or the like from the signal lines. Accordingly, images may be displayed toward a third direction DR3 crossing each of the first direction DR1 and the second direction and DR2 in the display area DA. For example, the third direction DR3 may be perpendicular or normal to each of the first direction DR1 and the second direction DR2.

According to some embodiments, the display device 10 may be a micro light emitting diode display device including a micro light emitting element as a light emitting element. However, embodiments according to the present disclosure are not limited thereto.

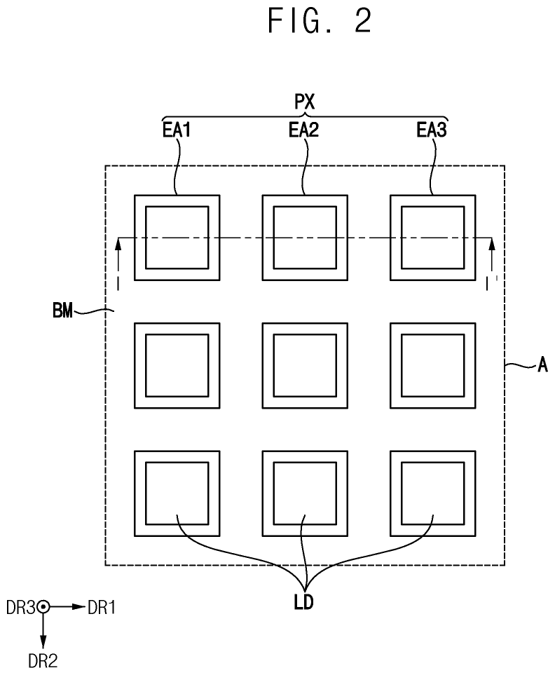

FIG. 2 is an enlarged plan view of the area A of FIG. 1.

Referring to FIGS. 1 and 2, each of the pixels PX may include a first light emitting area EA1, a second light emitting area EA2 and a third light emitting area EA3 that emit light. Although FIG. 2 illustrates that each of the pixels PX includes three light emitting areas EA1, EA2 and EA3, embodiments according to the present disclosure are not limited thereto. For example, each of the pixels PX may include four or more light emitting areas.

Each of the first, second and third light emitting areas EA1, EA2, and EA3 may include a light emitting element LD that emits first light. For example, the first light may be white light, but embodiments according to the present disclosure are not limited thereto. In addition, although FIG. 2 illustrates that the light emitting element LD has a rectangular planar shape, but embodiments according to the present disclosure are not limited thereto. For example, the light emitting element LD may have a polygonal shape, a circular shape, an elliptical shape, or an atypical shape other than the rectangular shape.

The first light emitting area EA1 may emit second light. The first light emitting area EA1 may convert the first light emitted from the light emitting element LD into the second light and may emit the second light. For example, the second light may be light in a blue wavelength band, but embodiments according to the present disclosure are not limited thereto.

The second light emitting area EA2 may emit third light. The second light emitting area EA2 may convert the first light emitted from the light emitting element LD into the third light and may emit the third light. For example, the third light may be light in a green wavelength band, but embodiments according to the present disclosure are not limited thereto.

The third light emitting area EA3 may emit fourth light. The third light emitting area EA2 may convert the first light emitted from the light emitting element LD into the fourth light and may emit the fourth light. For example, the fourth light may be light in a red wavelength band, but embodiments according to the present disclosure are not limited thereto.

The first light emitting area EA1, the second light emitting area EA2 and the third light emitting area EA3 may be arranged along the first direction DR1. For example, the first light emitting area EA1, the second light emitting area EA2 and the third light emitting area EA3 may be arranged in an order of the first light emitting area EA1, the second light emitting area EA2 and the third light emitting area EA3 in the first direction DR1. In addition, each of the first light emitting area EA1, the second light emitting area EA2 and the third light emitting area EA3 may be arranged along the second direction DR2. However, the embodiments according to the present disclosure are not limited thereto.

The first, second and third light emitting areas EA1, EA2 and EA3 may be defined by a light blocking part BM. The light blocking part BM may surround each of the first, second and third light emitting areas EA1, EA2 and EA3. The light blocking part BM may have a mesh shape, a net shape or a lattice shape in the plan view.

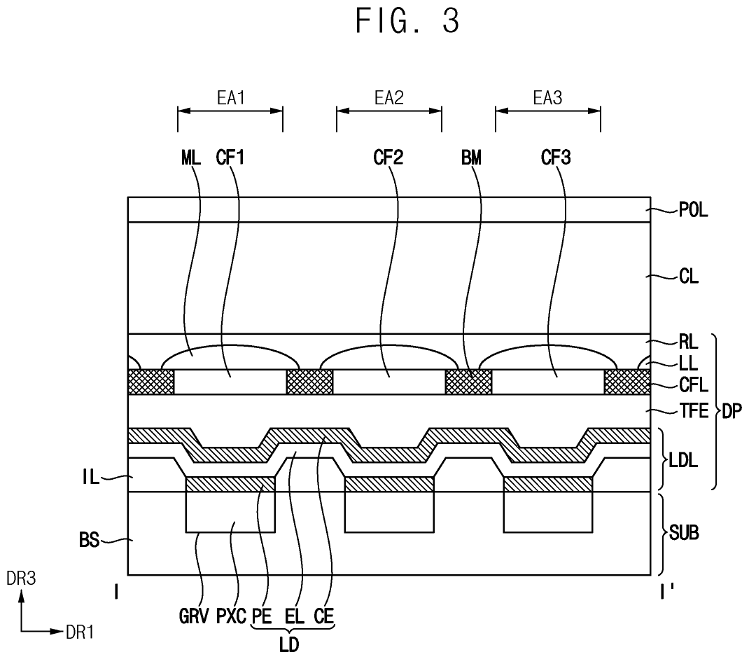

FIG. 3 is a cross-sectional view taken along the line I-I′ of FIG. 2.

Referring to FIGS. 1, 2 and 3, the display device 10 may include a substrate SUB, a display part DP, a coating layer CL and a polarization layer POL.

According to some embodiments, the substrate SUB may be a semiconductor circuit board. The substrate SUB may include a base substrate BS and a plurality of pixel circuit parts PXC. The base substrate BS may include a silicon wafer. In addition, the base substrate BS may define a plurality of grooves GRV. The pixel circuit parts PXC may be accommodated in the grooves GRV, respectively.

Each of the pixel circuit parts PXC may include at least one transistor. In addition, each of the pixel circuit parts PXC may further include at least one capacitor.

The display part DP may be located on the substrate SUB. The display part DP may include a light emitting element layer LDL, an encapsulation layer TFE, a color filter layer CFL, a lens layer LL and a low refractive index layer RL.

The light emitting element layer LDL may be located on the substrate SUB. The light emitting element layer LDL may include a plurality of light emitting elements LD and an insulating layer IL. Each of the light emitting elements LD may include a pixel electrode PE, a light emitting layer EL and a common electrode CE.

The insulating layer IL may be located on the substrate SUB. The insulating layer IL may define openings exposing the plurality of pixel circuit parts PXC.

The pixel electrode PE may be located on the pixel circuit part PXC. The pixel electrode PE may be located in the opening defined in the insulating layer IL. The pixel electrode PE may be connected to the pixel circuit part PXC. Accordingly, the pixel electrode PE may receive a pixel voltage or an anode voltage from the pixel circuit part PXC. The pixel electrode PE may include a metal, an alloy, a conductive metal oxide, a transparent conductive material, or the like. These may be used alone or in combination with each other.

The light emitting layer EL may be located on the pixel electrode PE and the insulating layer IL. The light emitting layer EL may include an organic material that emits light of a predetermined color. The light emitting layer EL may further include at least one of a hole injection layer, a hole transport layer, an electron transport layer, or an electron injection layer as an auxiliary layer for assisting light emitting in some cases. The light emitting layer EL may extend along the first, second, and third light emitting areas EA1, EA2, and EA3. However, embodiments according to the present disclosure are not limited thereto.

The common electrode CE may be located on the light emitting layer EL. The common electrode CE may include a metal, an alloy, a metal nitride, a conductive metal oxide, a transparent conductive material, or the like. These may be used alone or in combination with each other. The common electrode CE may extend along the first, second and third light emitting areas EA1, EA2, and EA3. However, embodiments according to the present disclosure are not limited thereto.

Accordingly, the light emitting elements LD including the pixel electrode PE, the light emitting layer EL and the common electrode CE may be located on the substrate SUB. In this case, the light emitting layer EL may emit light based on a voltage difference between the pixel electrode PE and the common electrode CE.

The encapsulation layer TFE may be located on the light emitting element layer LDL. The encapsulation layer TFE may include at least one inorganic encapsulation layer and at least one organic encapsulation layer. For example, the inorganic encapsulation layer and the organic encapsulation layer may be alternately stacked with each other. The encapsulation layer TFE may prevent or reduce instances of foreign substances or contaminants penetrating into the light emitting element layer LDL.

The color filter layer CFL may be located on the encapsulation layer TFE. The color filter layer CFL may include the light blocking part BM, a first color filter CF1, a second color filter CF2 and a third color filter CF3.

The light blocking part BM may be located on the encapsulation layer TFE. The light blocking part BM may define the first light emitting area EA1, the second light emitting area EA2 and the third light emitting area EA3. That is, the light blocking part BM may define a plurality of openings that partition the first, second third light emitting areas EA1, EA2 and EA3. Accordingly, the light blocking part BM may not overlap the first, second and third light emitting areas EA1, EA2, and EA3. The light blocking part BM may include an organic material and/or an inorganic material including black pigment or black dye.

The first, second and third color filters CF1, CF2, and CF3 may be respectively located in the openings defined by the light blocking part BM.

The first color filter CF1 may be arranged to overlap the first light emitting area EA1. The first color filter CF1 may transmit the second light among the first light emitted from the light emitting element layer LDL, and may absorb or block the third light and the fourth light. For example, the first color filter CF1 may transmit light in a blue wavelength band, and may absorb or block light in other wavelength bands, such as green and red, but embodiments according to the present disclosure are not limited thereto.

The second color filter CF2 may be arranged to overlap the second light emitting area EA2. The second color filter CF2 may transmit the third light, and may absorb or block the second light and the fourth light. For example, the second color filter CF2 may transmit light in a green wavelength band, and may absorb or block light in other wavelength bands, such as blue and red, but embodiments according to the present disclosure are not limited thereto.

The third color filter CF3 may be arranged to overlap the third light emitting area EA3. The third color filter CF3 may transmit the fourth light, and may absorb or block the second light and the third light. For example, the third color filter CF3 may transmit light in a red wavelength band, and may absorb or block light in other wavelength bands, such as blue and green, but embodiments according to the present disclosure are not limited thereto.

Although FIG. 3 illustrates that the color filter layer CFL includes the light blocking part BM and the first, second and third color filters CF1, CF2 and CF3, embodiments according to the present disclosure are not limited thereto. For example, the color filter layer CFL may further include a reflector, or may include a reflector instead of the light blocking part BM.

The lens layer LL may be located on the color filter layer CFL. The lens layer LL may include a plurality of micro lenses ML. The micro lenses ML may be respectively located on the first, second and third color filters CF1, CF2 and CF3. The micro lenses ML may have a predetermined refractive index. For example, the micro lenses ML may have the refractive index in a range of about 1.5 to about 1.7. However, embodiments according to the present disclosure are not limited thereto. The micro lenses ML may improve light extraction efficiency.

The low refractive index layer RL may be located on the lens layer LL. The low refractive index layer RL may cover the micro lenses ML. According to some embodiments, the low refractive index layer RL may include fluorine or hollow silica. The low refractive index layer RL may have a predetermined refractive index. The refractive index of the low refractive index layer RL may be smaller than the refractive index of the micro lenses ML. For example, the low refractive index layer RL may have the refractive index in a range of about 1.2 to about 1.4. According to some embodiments, a difference between the refractive index of the low refractive index layer RL and the refractive index of the micro lenses ML may be in a range of about 0.1 to about 0.5. However, embodiments according to the present disclosure are not limited thereto. The low refractive index layer RL may improve light efficiency of the display device 10.

The coating layer CL may be located on the low refractive index layer RL. According to some embodiments, the coating layer CL may include poly silsesquioxane or siloxane.

The polarization layer POL may be located on the coating layer CL. The polarization layer POL may reduce reflection of external light of the display device 10. As external light reflection is reduced, visibility of the display device 10 may be relatively improved.

Although FIG. 3 illustrates that the display device 10 includes one low refractive index layer RL and one coating layer CL, embodiments according to the present disclosure are not limited thereto. For example, the low refractive index layer RL and the coating layer CL may be one layer.

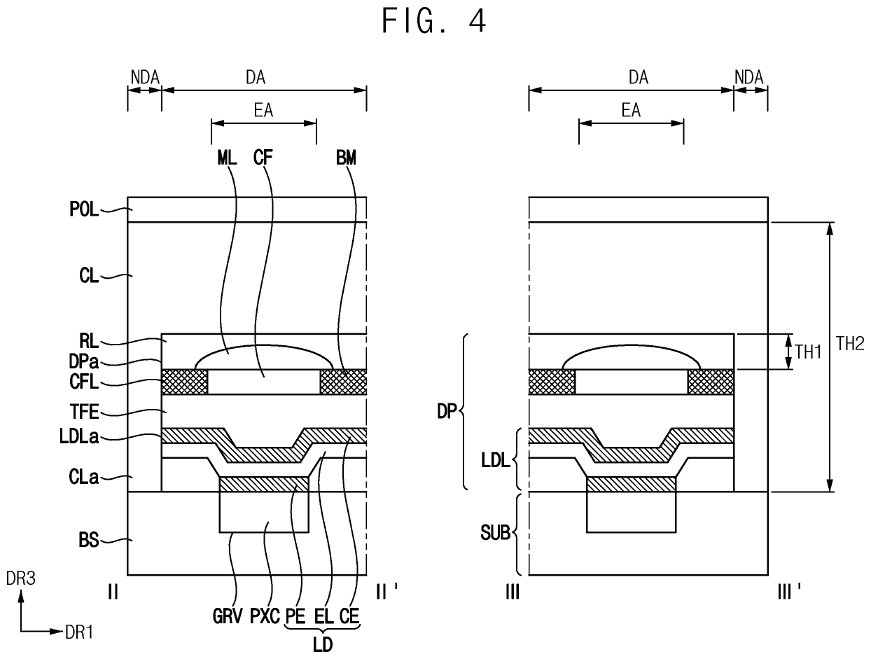

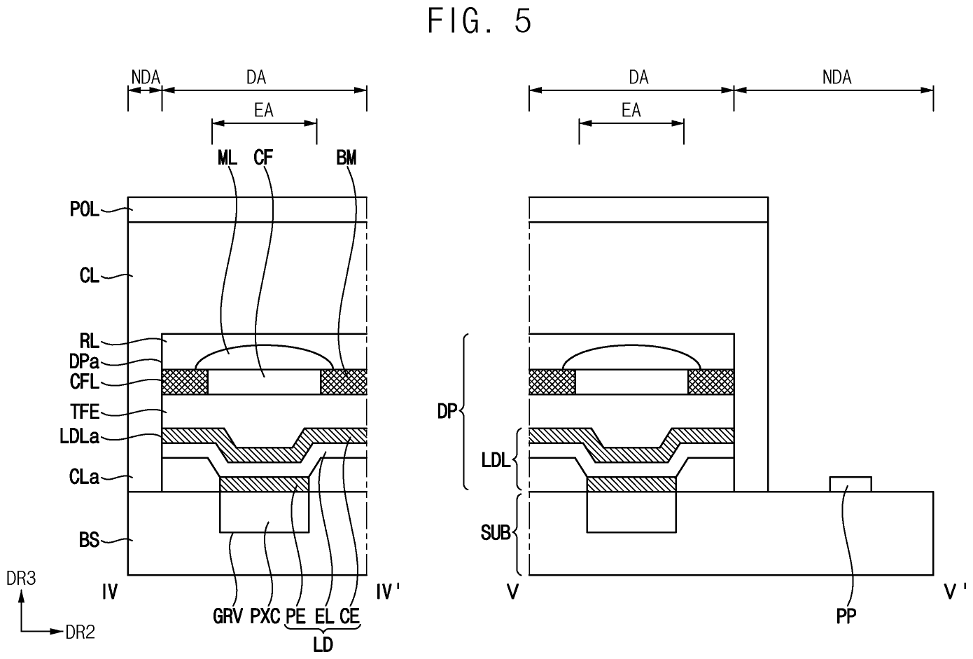

FIG. 4 is a cross-sectional view taken along the lines II-II′ and III-III′ of FIG. 1. FIG. 5 is a cross-sectional view taken along the lines IV-IV′ and V-V′ of FIG. 1.

Referring to FIGS. 1, 4 and 5, the display device 10 may include the substrate SUB, the display part DP, the coating layer CL, the polarization layer POL and a pad part PP.

The coating layer CL may be located in the display area DA and the non-display area NDA on the substrate SUB. For example, the coating layer CL may entirely overlap the display area DA, and may partially overlap the non-display area NDA.

The coating layer CL may contact the substrate SUB in the non-display area NDA. In addition, the coating layer CL may cover a side surface LDLa of the light emitting element layer LDL. For example, the coating layer CL may extend from an upper surface of the display part DP along a side surface DPa of the display part DP to contact an upper surface of the substrate SUB. That is, a side surface CLa of the coating layer CL may contact the side surface DPa of the display part DP and the substrate SUB in the non-display area NDA.

According to some embodiments, a thickness TH1 of the low refractive index layer RL may be in a range of about 10 μm to about 15 μm. In addition, a thickness TH2 of the coating layer CL may in a range of about 300 μm to about 600 μm. In this case, the thickness TH1 of the low refractive index layer RL and the thickness TH2 of the coating layer CL may be lengths of the low refractive index layer and the coating layer CL in the third direction DR3, respectively.

The polarization layer POL may be located on the coating layer CL, and may entirely overlap the coating layer CL. That is, the polarization layer POL may entirely overlap the display area DA, and may partially overlap the non-display area NDA.

The pad part PP may be located in the non-display area NDA on one side of the substrate SUB. For example, the pad part PP may be located in the non-display area NDA on a lower side of the substrate SUB. The pad part PP may be connected to a printed circuit board or the like.

The pad part PP may be spaced apart from the light emitting element layer LDL. In addition, the pad part PP may be spaced apart from the coating layer CL. That is, the coating layer CL may not cover the pad part PP. In other words, the coating layer CL may cover the side surface DPa of the display part DP between the display part DP and the pad part PP.

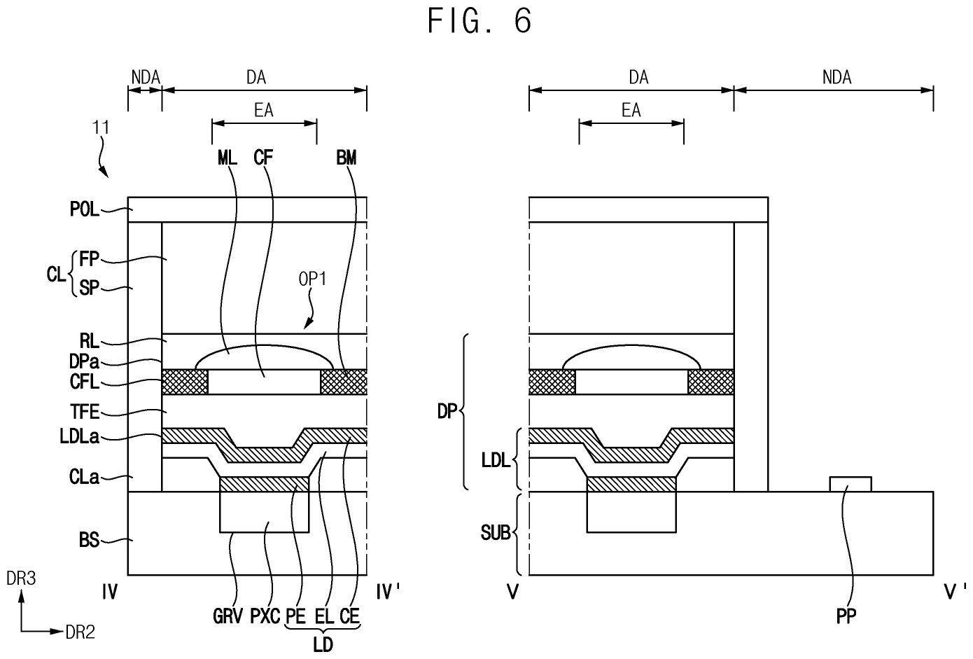

FIG. 6 is a cross-sectional view illustrating another example of FIG. 5.

Hereinafter, descriptions overlapping those of the display device 10 described with reference to FIGS. 4 and 5 will be omitted or simplified.

Referring to FIGS. 1 and 6, a display device 11 may include a substrate SUB, a display part DP, a coating layer CL, a polarization layer POL and a pad part PP.

The coating layer CL may be located on the display part DP. According to some embodiments, the coating layer CL may include a sealing part SP and a filling part FP.

The sealing part SP may form a side surface CLa of the coating layer CL. The sealing part SP may contact the substrate SUB in a non-display area NDA. In addition, the sealing part SP may cover a side surface LDLa of a light emitting element layer LDL. For example, the sealing part SP may extend along a side surface DPa of the display part DP, and may contact an upper surface of the substrate SUB. That is, the sealing part SP may contact the side surface DPa of the display part DP and the substrate SUB in the non-display area NDA.

According to some embodiments, the sealing part SP may define a first opening OP1 overlapping the lens layer LL. The first opening OP1 may overlap the display part DP. That is, the sealing part SP may surround a display area DA in the plan view.

The filling part FP may form an upper surface of the coating layer CL. The filling part FP may contact an upper surface of the display part DP in the display area DA. In addition, the filling part FP may be spaced apart from the substrate SUB. That is, the filling part FP may fill the first opening OP1 defined by the sealing part SP. In other words, the filling part FP may contact the display part DP in the first opening OP1.

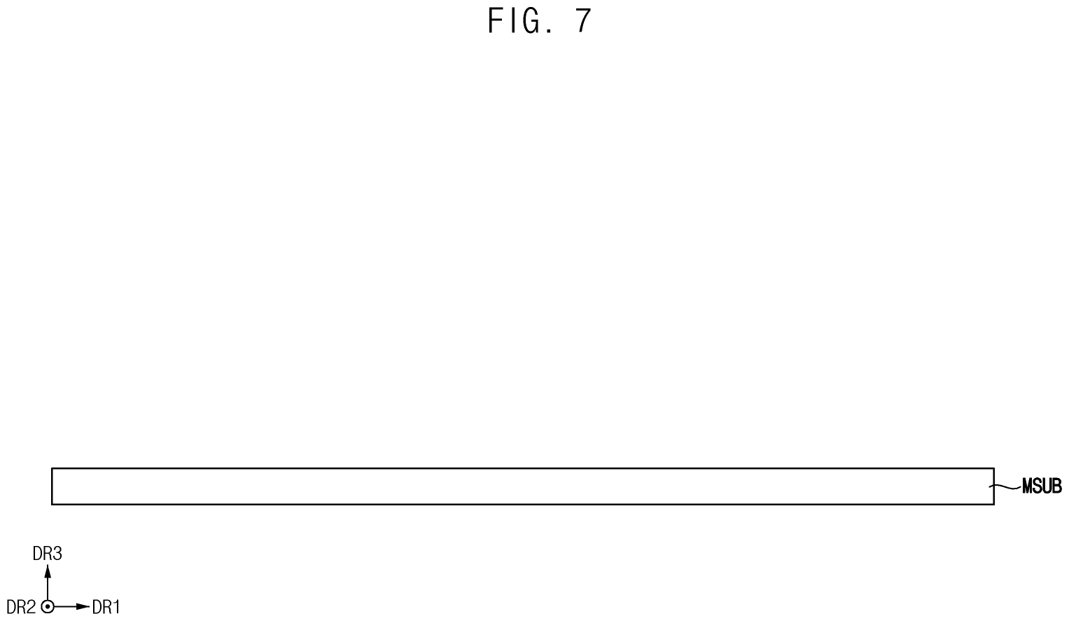

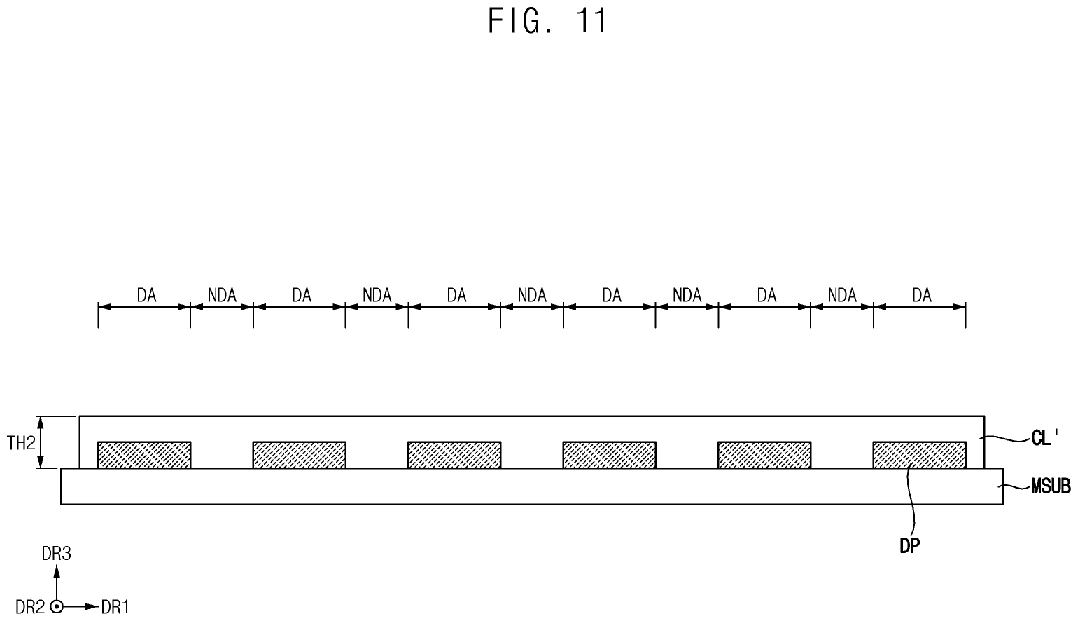

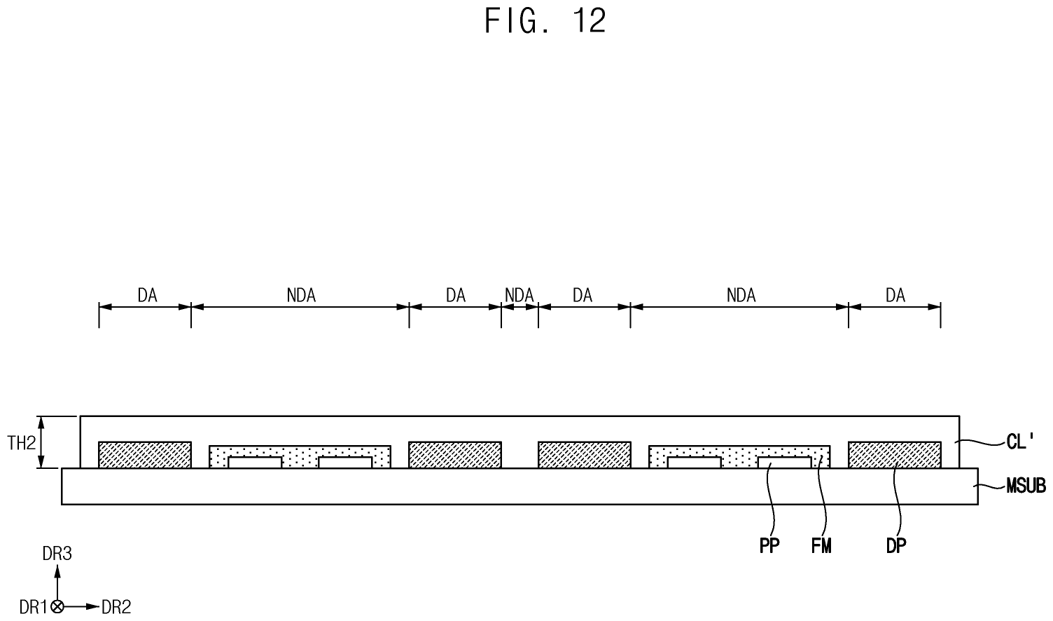

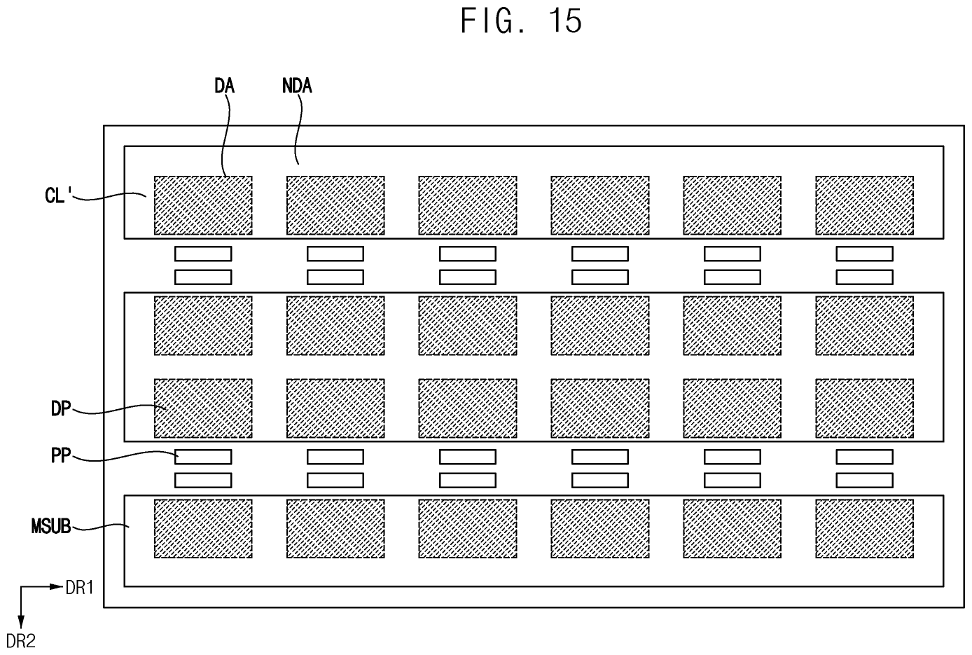

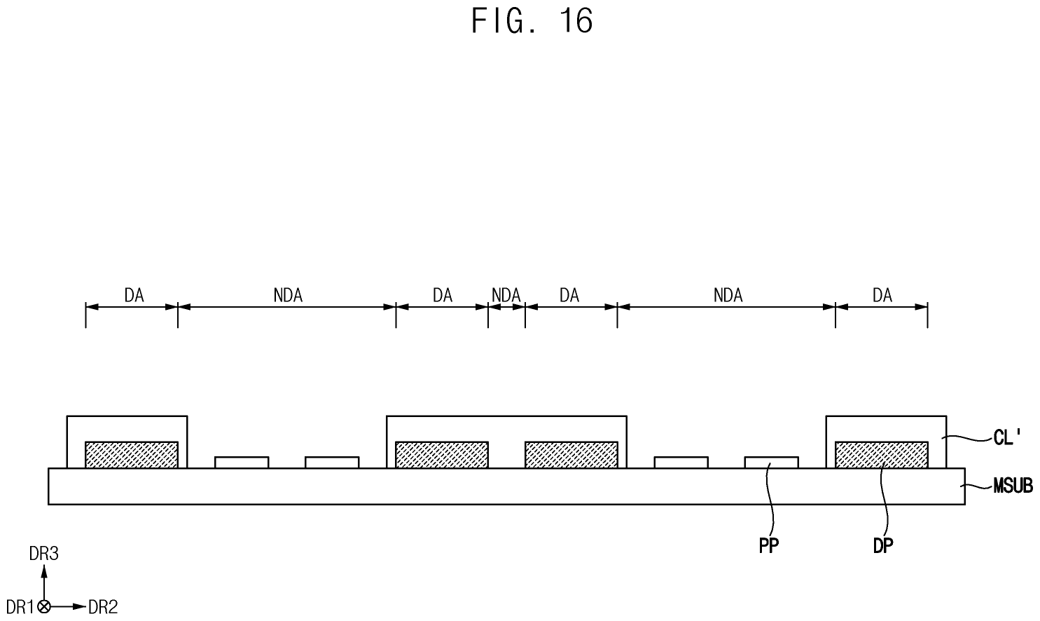

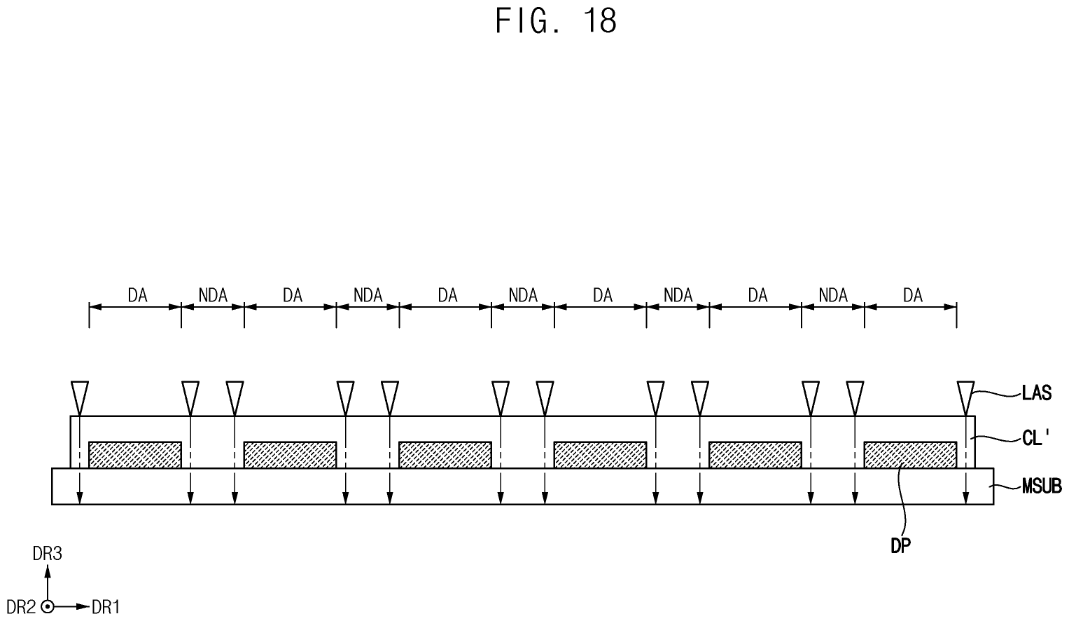

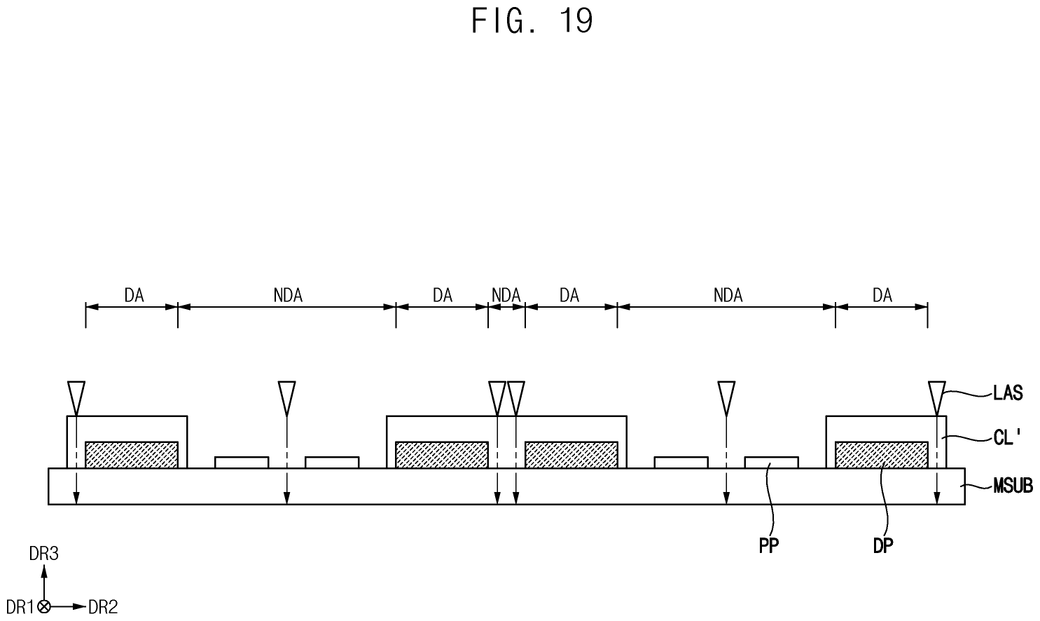

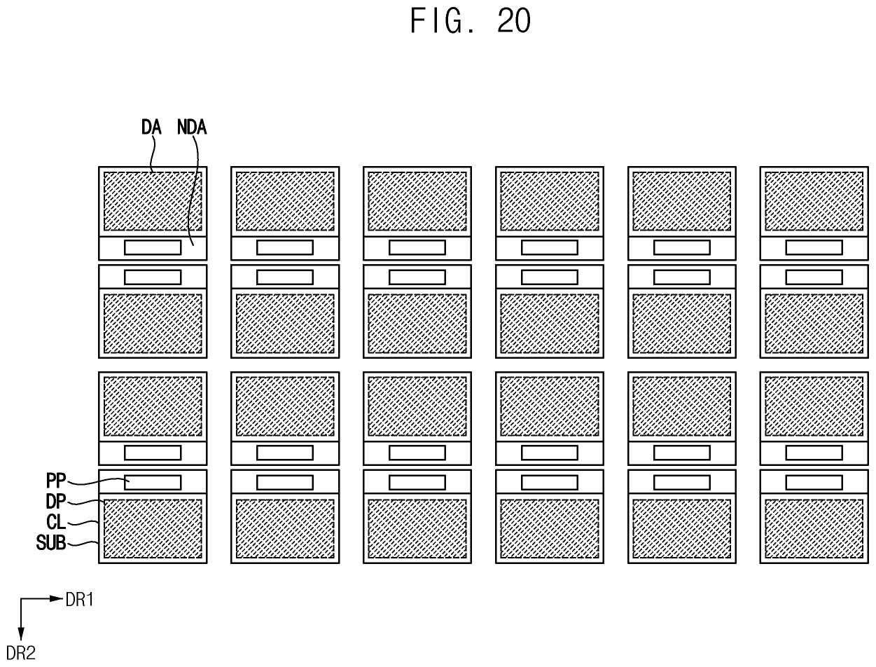

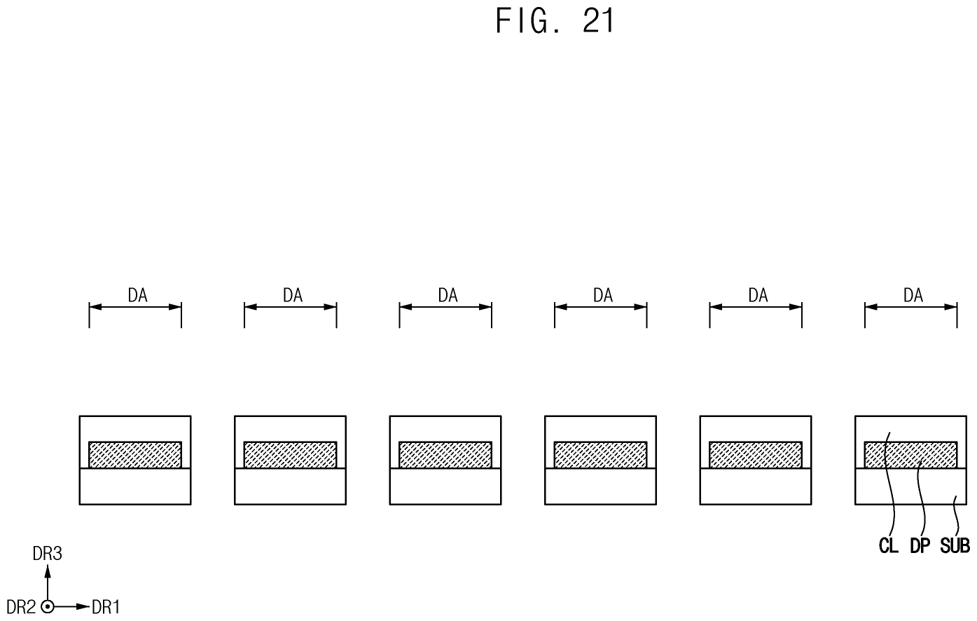

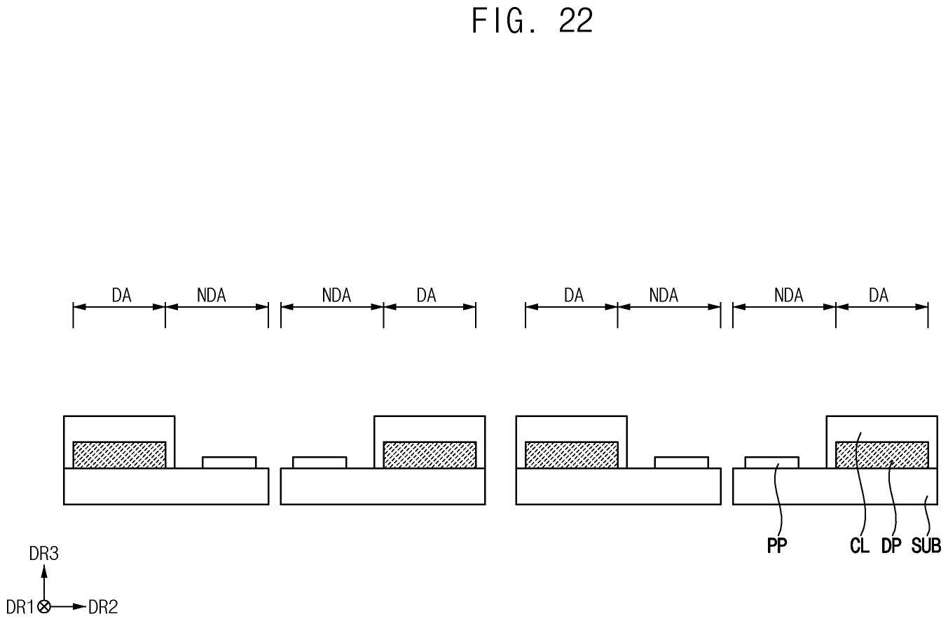

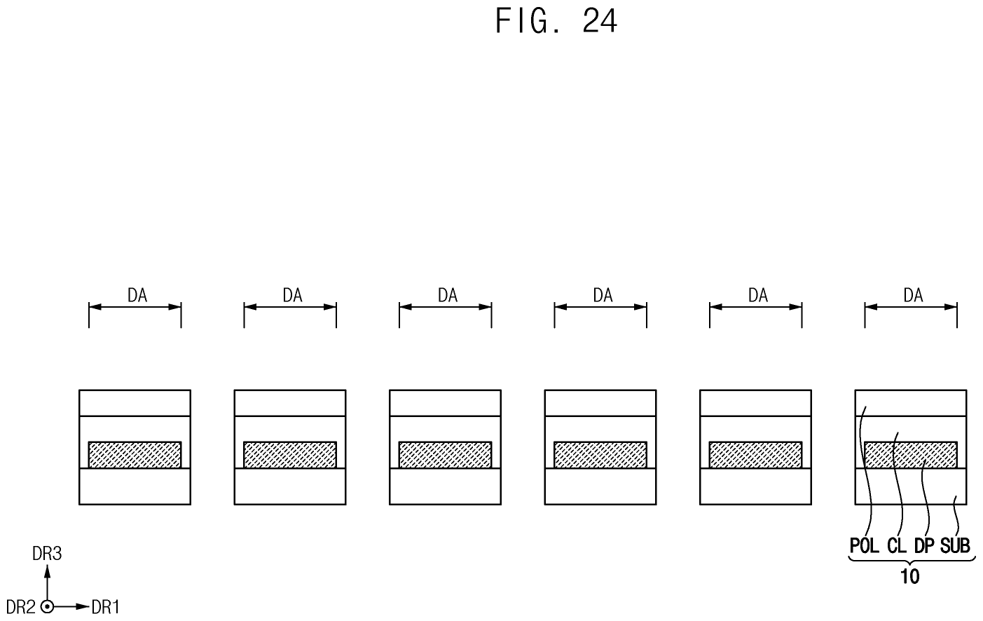

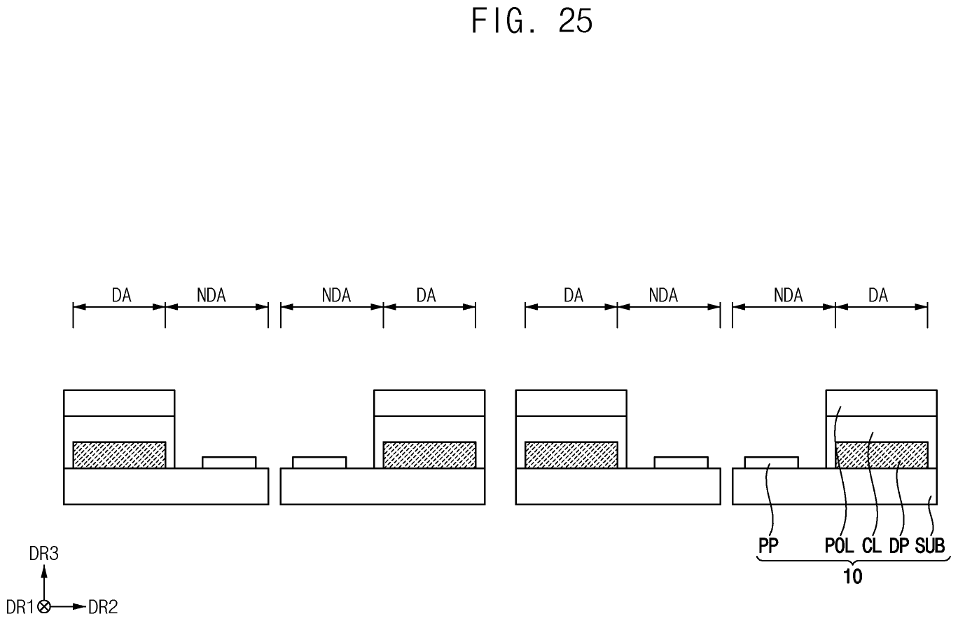

FIGS. 7 to 25 are views illustrating a method of manufacturing a display device according to some embodiments of the present disclosure.

A method of manufacturing a display device described with reference to FIGS. 7 to 25 may be a method of manufacturing the display device 10 described with reference to FIGS. 1, 2, 3, 4 and 5. Accordingly, redundant descriptions will be omitted or simplified.

Referring to FIG. 7, a mother substrate MSUB may be provided.

The mother substrate MSUB may be formed of a silicon wafer. The mother substrate MSUB may include a plurality of substrates (e.g., the substrate SUB of FIG. 3). That is, the plurality of substrates may be formed by cutting the mother substrate MSUB. In addition, a plurality of pixel circuit parts (e.g., the pixel circuit parts PXC of FIG. 3) may be formed on the mother substrate MSUB.

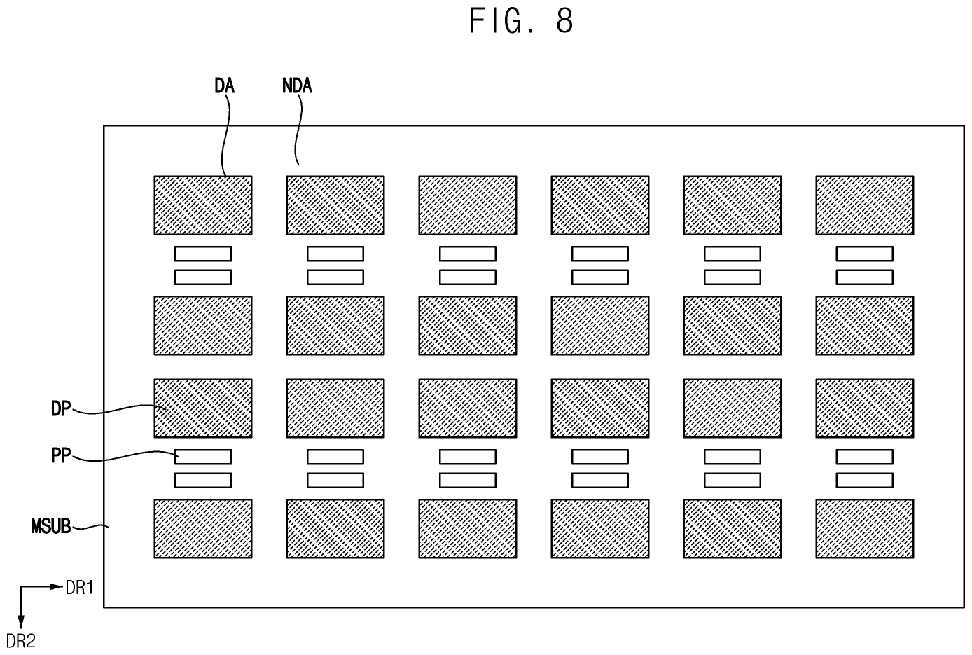

Referring to FIG. 8, a plurality of display parts DP and a plurality of pad parts PP may be formed on the mother substrate MSUB.

The display parts DP may be respectively formed in the display area DA on the mother substrate MSUB. Each of the display parts DP may include a light emitting element layer (e.g., the light emitting element layer LDL of FIG. 3). That is, a plurality of light emitting elements (e.g., the light emitting element LD of FIG. 2) may be formed on the mother substrate MSUB. In addition, an encapsulation layer (e.g., the encapsulation layer TFE in FIG. 3), a color filter layer (e.g., the color filter layer CFL in FIG. 3), a lens layer (e.g., the lens layer LL of FIG. 3) and the low refractive index layer (e.g., the low refractive index layer RL of FIG. 3) may be sequentially formed on the light emitting element layer.

The pad parts PP may be formed in the non-display area NDA on the mother substrate MSUB. For example, the non-display area NDA may surround the display area DA.

Although FIG. 8 illustrates that 24 display parts DP and 24 pad parts PP are formed on the mother substrate MSUB, embodiments according to the present disclosure are not limited thereto. For example, 23 or less or 25 or more display parts DP and pad parts PP may be formed on the mother substrate MSUB, respectively.

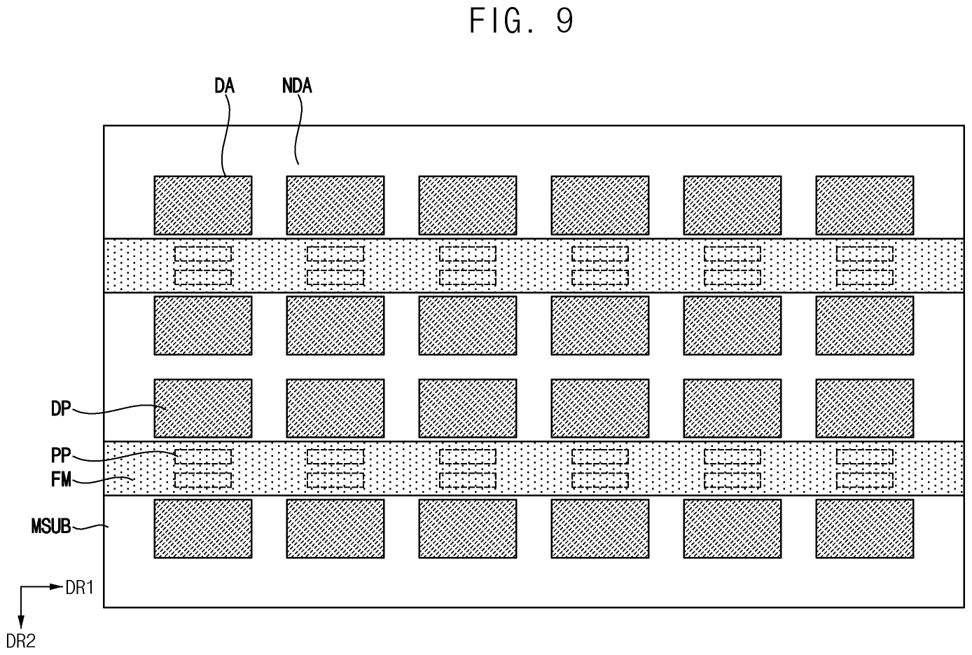

Referring to FIG. 9, a plurality of release films FM may be attached to the mother substrate MSUB.

The release films FM may be attached to the non-display area NDA on the mother substrate MSUB. According to some embodiments, the release films FM may cover the pad parts PP. For example, each of the release films FM may extend in the first direction DR1 to cover the pad parts PP arranged along the first direction DR1.

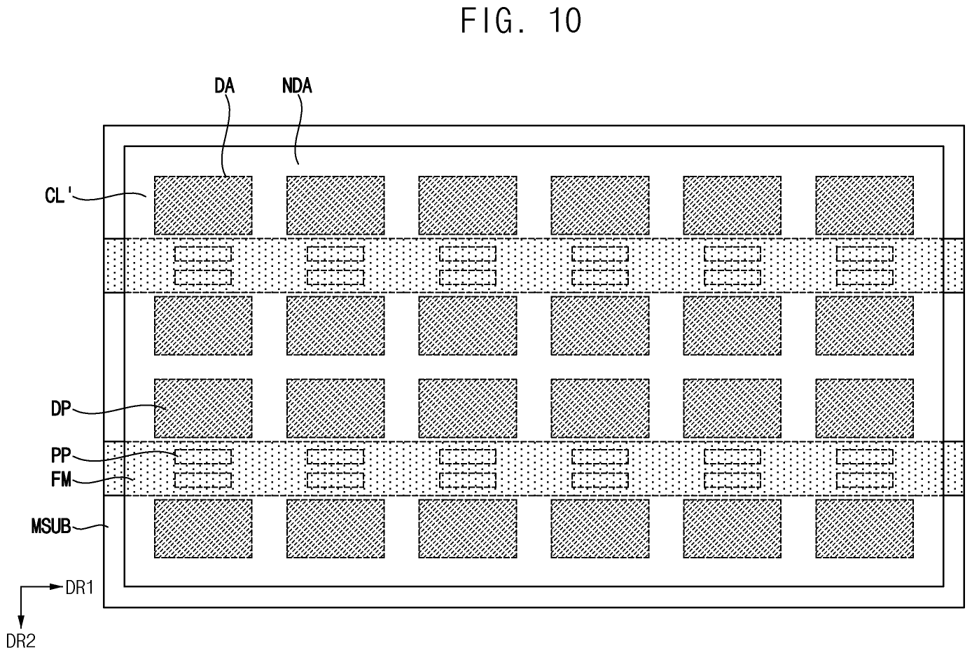

Referring to FIGS. 10, 11 and 12, a preliminary coating layer CL′ may be formed on the mother substrate MSUB.

The preliminary coating layer CL′ may be formed in the display area DA and the non-display area NDA on the mother substrate MSUB. For example, the preliminary coating layer CL′ may entirely overlap the display area DA, and may partially overlap the non-display area NDA. In addition, the preliminary coating layer CL′ may entirely overlap the display parts DP and the pad parts PP, and may partially overlap the release films FM. In other words, the preliminary coating layer CL′ may cover the display parts DP, and may cover the release films FM covering the pad parts PP.

According to some embodiments, the thickness TH2 of the preliminary coating layer CL′ may be in a range of about 300 μm to about 600 μm. However, embodiments according to the present disclosure are not limited thereto.

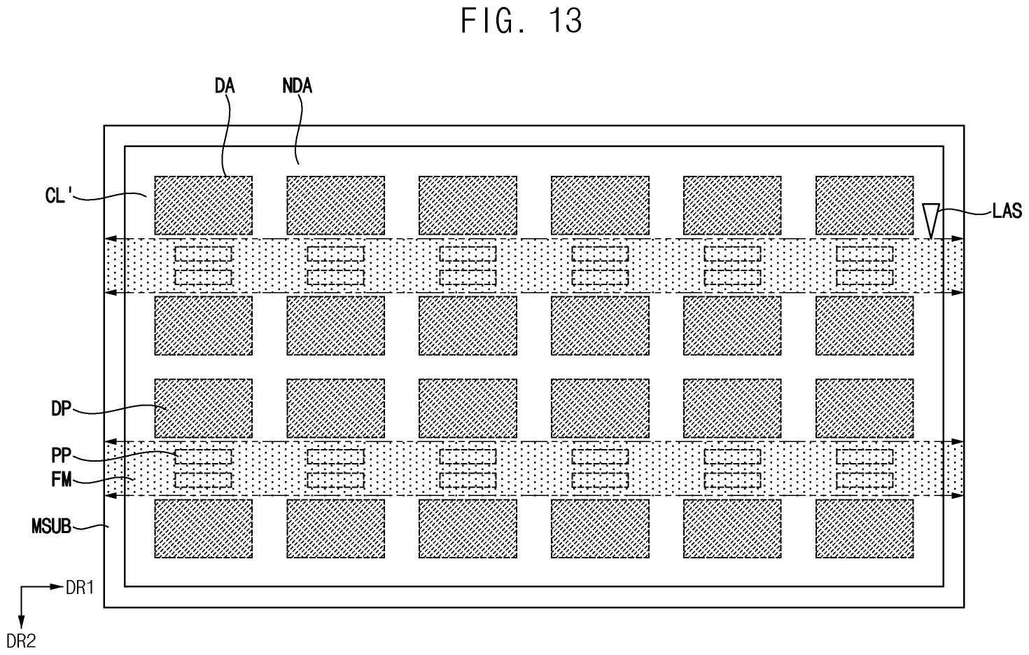

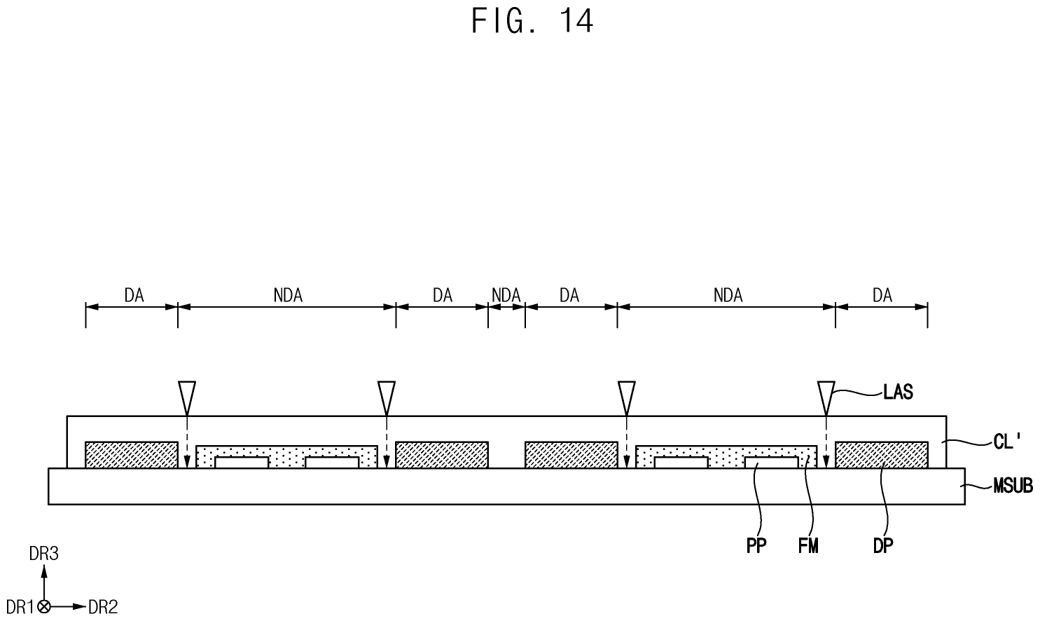

Referring to FIGS. 13 and 14, the preliminary coating layer CL′ may be cut.

According to some embodiments, the preliminary coating layer CL′ may be cut by a laser LAS. For example, the laser LAS may be irradiated in a direction from the preliminary coating layer CL′ to the mother substrate MSUB.

The preliminary coating layer CL′ may be cut along one side surface adjacent to the release film FM among a plurality of side surfaces of the display area DA. For example, the preliminary coating layer CL′ may be cut between one side surface adjacent to the pad part PP among a plurality of side surfaces of the display part DP and a side surface of the release film FM adjacent to the side surface of the display part DP. For example, the preliminary coating layer CL′ may be cut in the first direction DR1 along the side surface of the release films FM extending in the first direction DR1.

Referring to FIGS. 13, 14, 15 and 16, the release films FM and the preliminary coating layer CL′ overlapping the release films FM may be removed. For example, the release films FM and the preliminary coating layer CL′ overlapping the release films FM may be removed along lines in which the preliminary coating layer CL′ is cut. Accordingly, the pad parts PP may be exposed, and the display parts DP may be covered by the preliminary coating layer CL′.

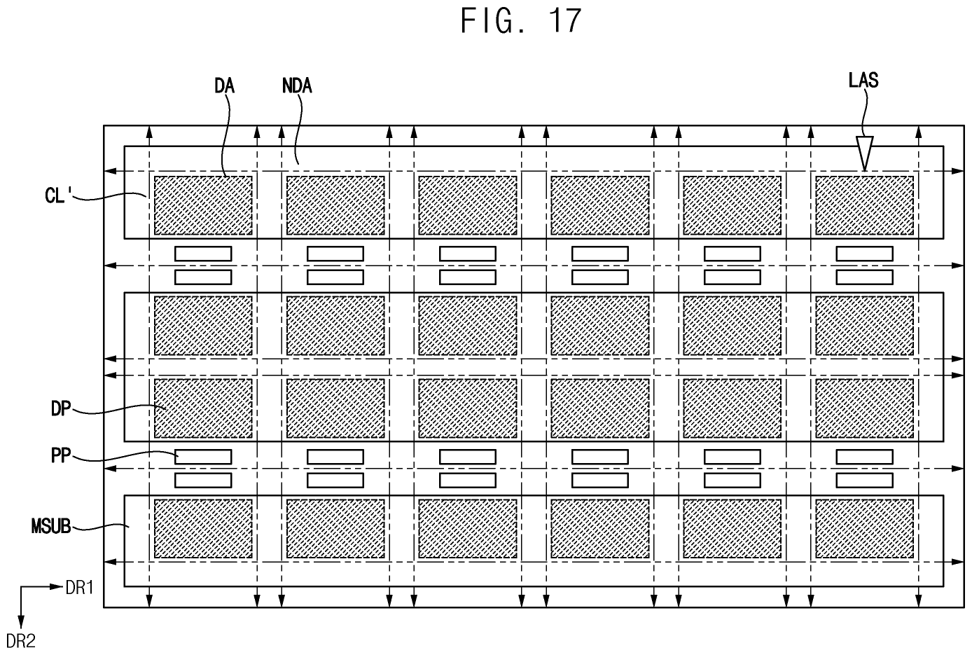

Referring to FIGS. 17, 18 and 19, the preliminary coating layer CL′ and the mother substrate MSUB may be cut.

According to some embodiments, the preliminary coating layer CL′ and the mother substrate MSUB may be simultaneously (or concurrently) cut by the laser LAS.

The preliminary coating layer CL′ and the mother substrate MSUB may be simultaneously (or concurrently) cut along other side surfaces among the plurality of side surfaces of the display area DA. That is, the preliminary coating layer CL′ and the mother substrate MSUB may be simultaneously (or concurrently) cut along other side surfaces among the plurality of side surfaces of the display part DP other than the side surface adjacent to the pad part PP of the display part DP. In addition, the preliminary coating layer CL′ and the mother substrate MSUB may be simultaneously (or concurrently) cut between the pad parts PP adjacent to each other. For example, the preliminary coating layer CL′ and the mother substrate MSUB may be simultaneously (or concurrently) cut in the first direction DR1 and in the second direction DR2 crossing the first direction DR1.

Referring to FIGS. 17, 18, 19, 20, 21 and 22, the coating layer CL may be formed by cutting the preliminary coating layer CL′. In addition, a plurality of substrates SUB may be formed by cutting the mother substrate MSUB.

The display part DP may be located in the display area DA on the substrate SUB, and the pad part PP may be located in the non-display area NDA on the substrate SUB. The coating layer CL may cover the display part DP. That is, the coating layer CL may cover the upper surface of the display part DP and the side surface of the display part DP, and may contact the substrate SUB.

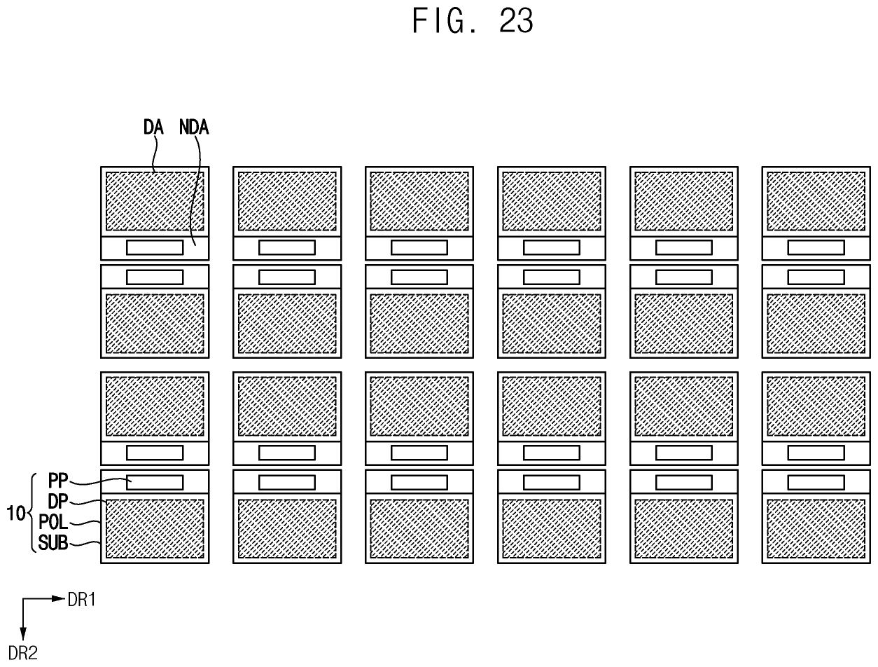

Referring to FIGS. 23, 24 and 25, the polarization layer POL may be formed on the coating layer CL. The polarization layer POL may entirely overlap the coating layer CL.

Accordingly, the display device 10 including the substrate SUB, the display part DP, the coating layer CL, the polarization layer POL and the pad part PP may be formed.

In the method of manufacturing the display device 10 according to some embodiments of the present disclosure, the preliminary coating layer CL′ covering the release film FM and the display part DP may be formed on the mother substrate MSUB. The release film FM may cover the pad part PP. Because the preliminary coating layer CL′ and the mother substrate MSUB may be simultaneously (or concurrently) cut by the laser LAS, an additional process for cutting the mother substrate MSUB may not be required. Therefore, a manufacturing process may be simplified and efficiency in the manufacturing process may be improved.

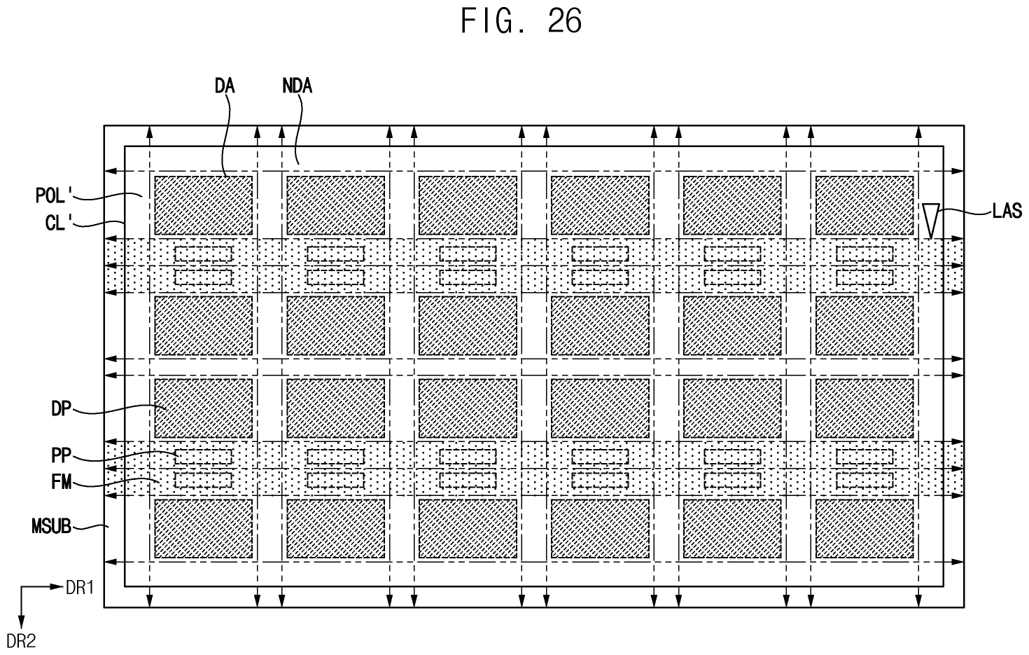

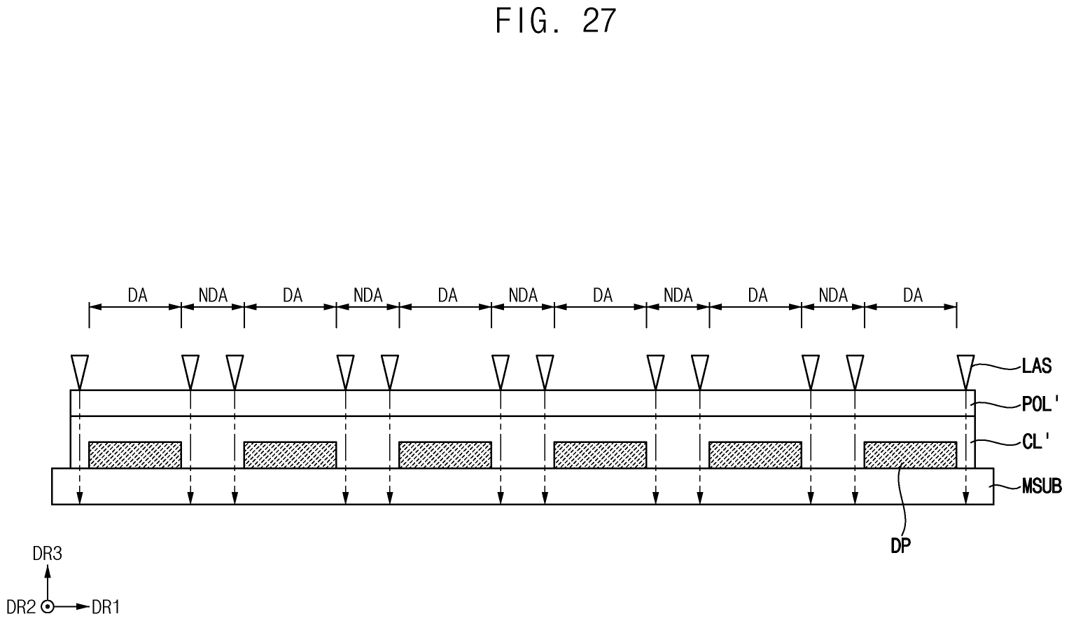

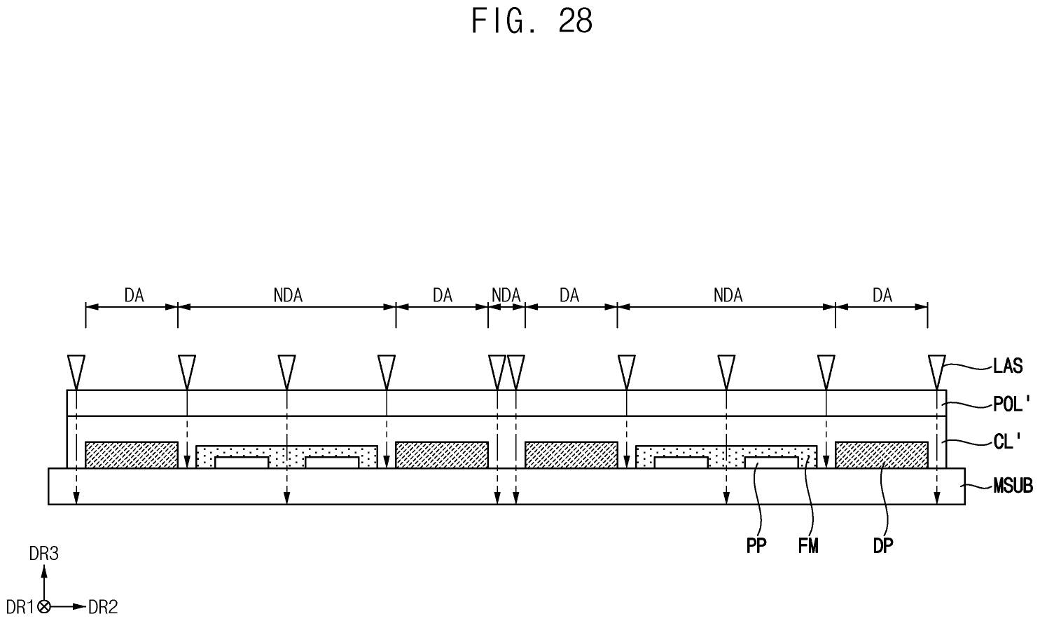

FIGS. 26, 27 and 28 are views illustrating a method of manufacturing a display device according to some embodiments of the present disclosure.

Hereinafter, descriptions overlapping those of the method of manufacturing the display device 10 described with reference to FIGS. 7 to 25 will be omitted or simplified.

Referring to FIGS. 23, 24, 25, 26, 27 and 28, the plurality of display parts DP, the plurality of pad parts PP, the plurality of release films FM and the preliminary coating layer CL′ may be formed on the mother substrate MSUB.

According to some embodiments, a preliminary polarization layer POL′ may be formed on the preliminary coating layer CL′. The preliminary polarization layer POL′ may entirely overlap the preliminary coating layer CL′. That is, the preliminary polarization layer POL′ may entirely overlap the display area DA, and may partially overlap the non-display area NDA. In addition, the preliminary polarization layer POL′ may entirely overlap the display parts DP and the pad parts PP, and may partially overlap the release films FM.

The preliminary coating layer CL′ and the preliminary polarization layer POL′ may be simultaneously (or concurrently) cut by the laser LAS. For example, the laser LAS may be irradiated in a direction from the preliminary polarization layer POL′ to the mother substrate MSUB.

The preliminary coating layer CL′ and the preliminary polarization layer POL′ may be simultaneously (or concurrently) cut along one side surface adjacent to the release film FM among a plurality of side surfaces of the display area DA. For example, the preliminary coating layer CL′ and the preliminary polarization layer POL′ may be simultaneously (or concurrently) cut between one side surface adjacent to the pad part PP among a plurality of side surfaces of the display part DP and a side surface of the release film FM adjacent to the side surface of the display part DP.

In addition, the preliminary coating layer CL′, the preliminary polarization layer POL′ and the mother substrate MSUB may be simultaneously (or concurrently) cut by the laser LAS.

The preliminary coating layer CL′, the preliminary polarization layer POL′ and the mother substrate MSUB may be simultaneously (or concurrently) cut along other side surfaces among the plurality of side surfaces of the display area DA. That is, the preliminary coating layer CL′, the preliminary polarization layer POL′ and the mother substrate MSUB may be simultaneously (or concurrently) cut along other side surfaces among the plurality of side surfaces of the display part DP other than the side surface adjacent to the pad part PP of the display part DP. In addition, the preliminary coating layer CL′, the preliminary polarization layer POL′ and the mother substrate MSUB may be simultaneously (or concurrently) cut between the pad parts PP adjacent to each other.

The coating layer CL may be formed by cutting the preliminary coating layer CL′. In addition, the polarization layer POL may be formed by cutting the preliminary polarization layer POL′. In addition, a plurality of substrates SUB may be formed by cutting the mother substrate MSUB.

Accordingly, the display device 10 including the substrate SUB, the display part DP, the coating layer CL, the polarization layer POL and the pad part PP may be formed.

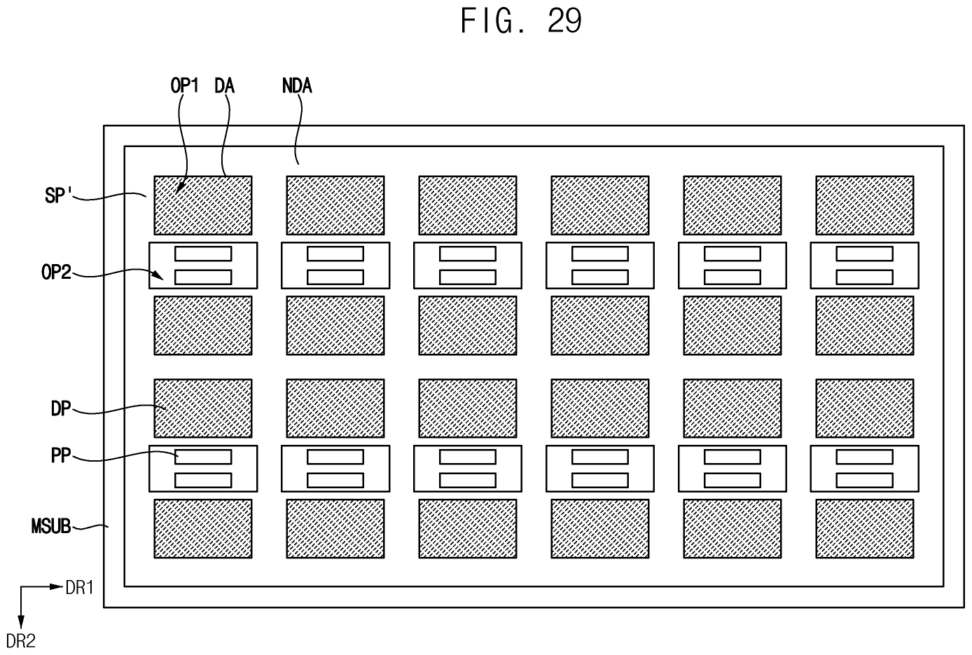

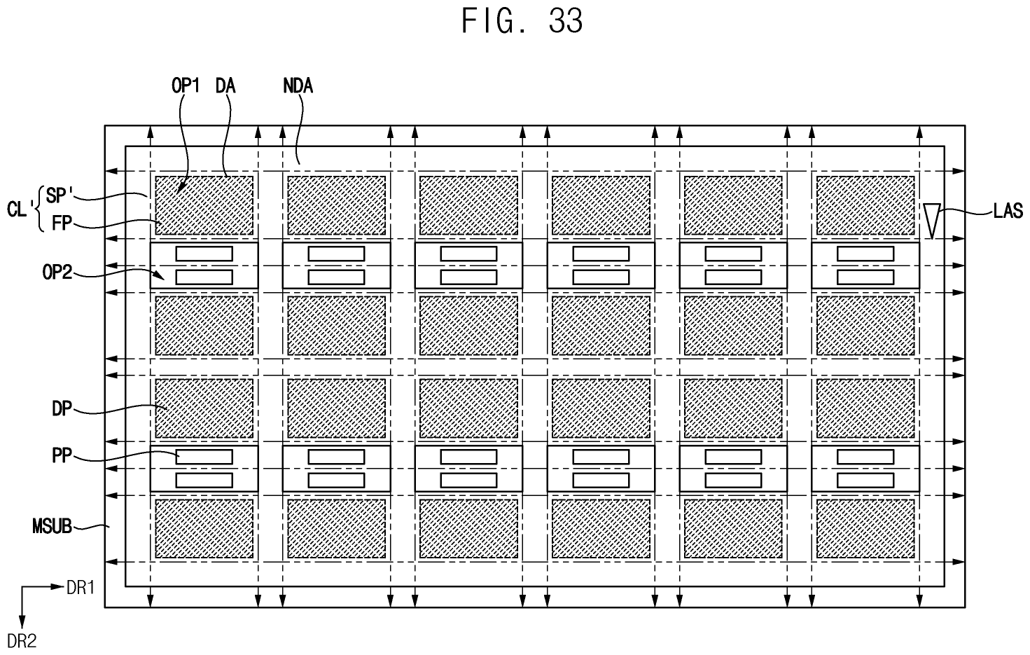

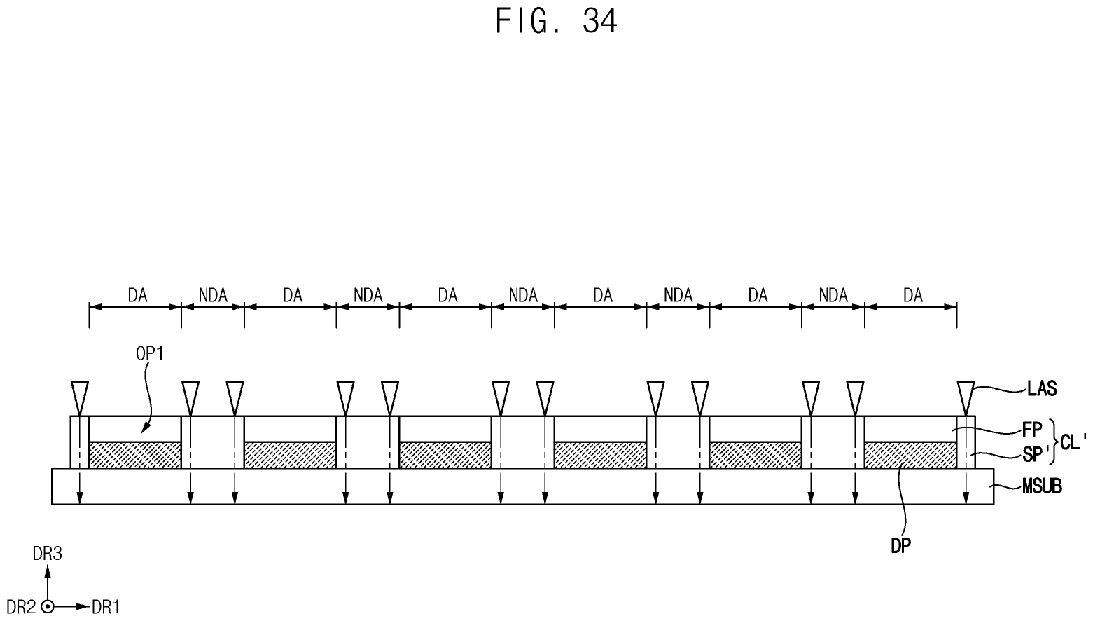

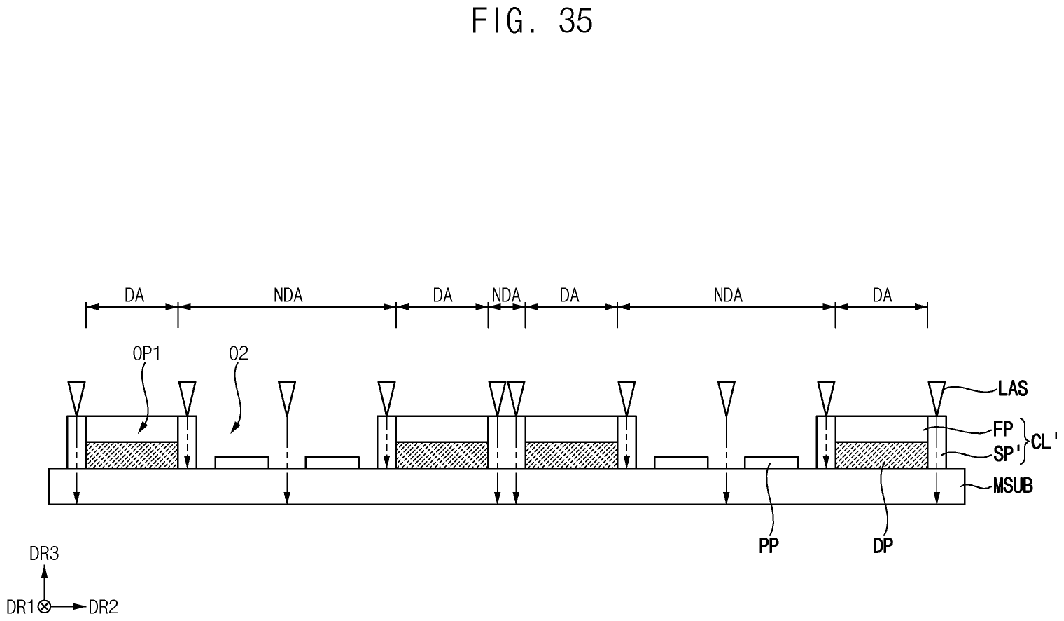

FIGS. 29 to 36 are views illustrating a method of manufacturing a display device according to some embodiments of the present disclosure.

A method of manufacturing a display device described with reference to FIGS. 29 to 36 may be a method of manufacturing the display device 11 described with reference to FIG. 6. Accordingly, redundant descriptions will be omitted or simplified.

In addition, descriptions overlapping those of the method of manufacturing the display device 10 described with reference to FIGS. 7 to 25 will be omitted or simplified.

Referring to FIG. 29, a plurality of display parts DP and a plurality of pad parts PP may be formed on the mother substrate MSUB.

A preliminary sealing part SP′ may be formed on the mother substrate MSUB. The preliminary sealing part SP′ may be formed in the non-display area NDA on the mother substrate MSUB. That is, the preliminary sealing part SP′ may surround the display area DA on the mother substrate MSUB. For example, the preliminary sealing part SP′ may cover side surfaces of each of the display parts DP.

According to some embodiments, the preliminary sealing part SP′ may define a plurality of first openings OP1 and a plurality of second openings OP2. For example, the first openings OP1 may respectively expose the display parts DP, and the second openings OP2 may respectively expose the pad parts PP.

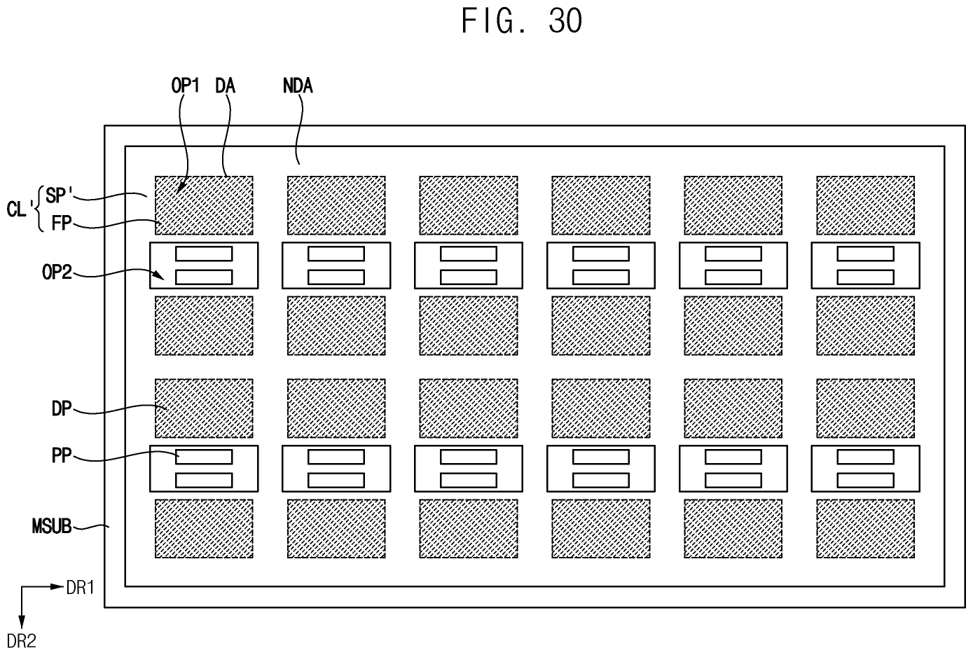

Referring to FIGS. 30, 31 and 32, the filling part FP may be formed on the display parts DP. The preliminary sealing part SP′ and the filling part FP may constitute a preliminary coating layer CL′.

The filling part FP may overlap the display area DA. According to some embodiments, the filling part FP may fill the first openings OP1 defined by the preliminary sealing part SP′. The filling part FP may contact the display parts DP in the first openings OP1. That is, the filling part FP may cover the upper surface of each of the display parts DP.

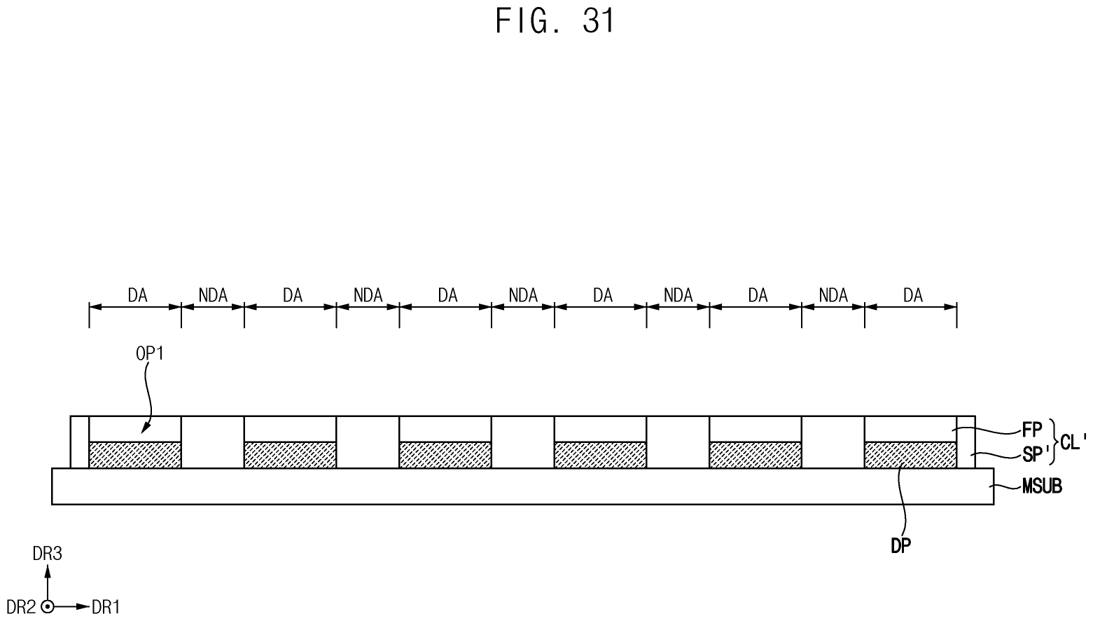

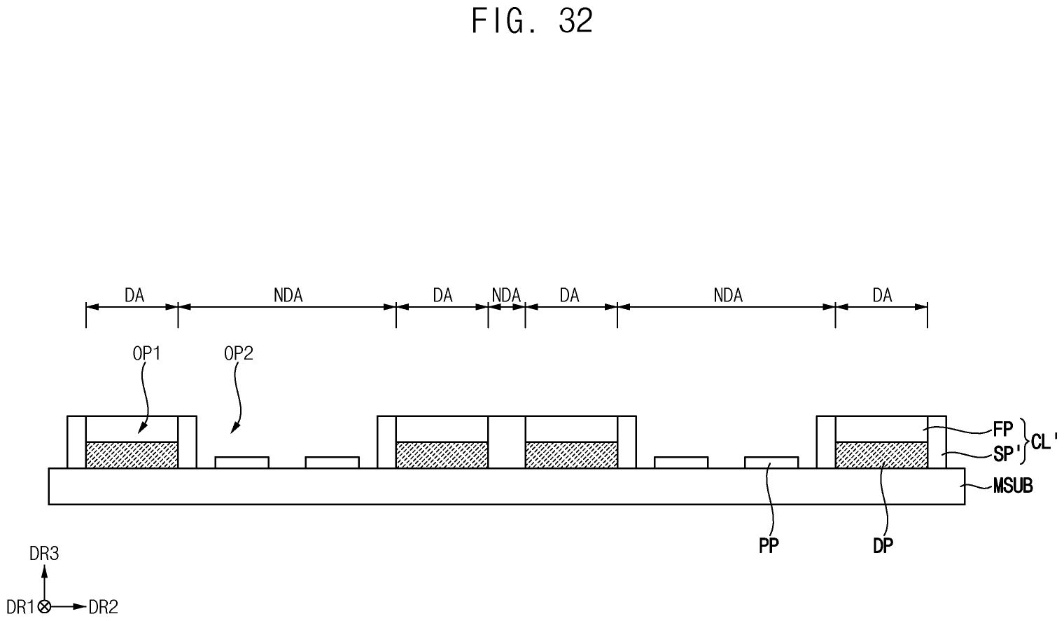

Although FIGS. 31 and 32 illustrate that upper surfaces of each of the preliminary sealing part SP′ and the filling part FP are located at a same level, embodiments according to the present disclosure are not limited thereto. For example, the upper surfaces of each of the preliminary sealing part SP′ and the filling part FP may be located at different levels from each other.

Referring to FIGS. 6, 33, 34 and 35, the preliminary coating layer CL′ and the mother substrate MSUB may be cut.

The preliminary sealing part SP′ included in the preliminary coating layer CL′ may be cut by a laser LAS. The preliminary sealing part SP′ may be cut along one side surface adjacent to the second opening OP2 among a plurality of side surfaces of the display area DA. For example, the preliminary sealing part SP′ may be cut between a side surface of the display part DP and a side surface of the second opening OP2 adjacent to the side surface of the display part DP.

In addition, the preliminary sealing part SP′ included in the preliminary coating layer CL′ and the mother substrate MSUB may be simultaneously (or concurrently) cut by the laser LAS. The preliminary sealing part SP′ and the mother substrate MSUB may be simultaneously (or concurrently) cut along other side surfaces among the plurality of side surfaces of the display area DA. In addition, the preliminary sealing part SP′ and the mother substrate MSUB may be simultaneously (or concurrently) cut between the pad parts PP adjacent to each other.

The sealing part SP may be formed by cutting the preliminary sealing part SP′. Accordingly, the coating layer CL including the sealing part SP and the filling part FP may be formed. In addition, a plurality of substrates SUB may be formed by cutting the mother substrate MSUB.

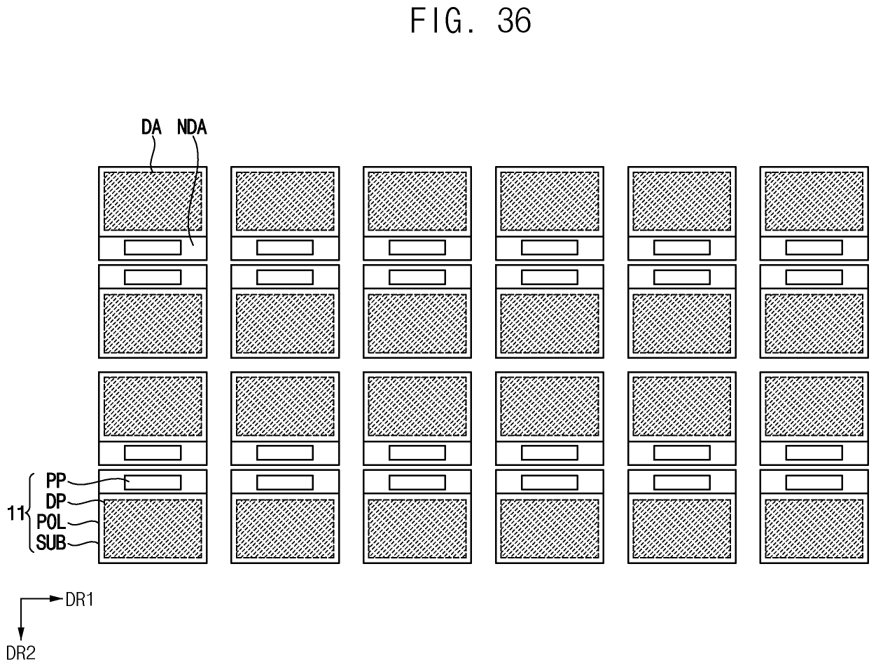

Referring to FIG. 36, the polarization layer POL may be formed on the coating layer CL. The polarization layer POL may entirely overlap the coating layer CL.

Accordingly, the display device 11 including the substrate SUB, the display part DP, the coating layer CL, the polarization layer POL and the pad part PP may be formed.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a substrate including a display area and a non-display area adjacent to the display area;
a light emitting element layer in the display area on the substrate and including a plurality of light emitting elements;
a pad part in the non-display area on the substrate and spaced apart from the light emitting element layer;
a lens layer on the light emitting element layer and including a plurality of micro lenses; and
a coating layer on the lens layer, covering a side surface of the light emitting element layer and contacting the substrate.

2. The display device of claim 1, wherein the coating layer includes poly silsesquioxane or siloxane.

3. The display device of claim 1, wherein a thickness of the coating layer is in a range of 300 μm to 600 μm.

4. The display device of claim 1, further comprising:
a low refractive index layer between the lens layer and the coating layer.

5. The display device of claim 4, wherein the low refractive index layer includes fluorine or hollow silica.

6. The display device of claim 4, wherein a refractive index of the low refractive index layer is smaller than a refractive index of the micro lenses, and
a difference between the refractive index of the low refractive index layer and the refractive index of the micro lenses is in a range of 0.1 to 0.5.

7. The display device of claim 1, wherein the substrate includes:
a base substrate defining a plurality of grooves and including a silicon wafer; and
a plurality of pixel circuit parts respectively accommodated in the plurality of grooves.

8. The display device of claim 1, wherein the coating layer includes:
a sealing part covering the side surface of the light emitting element layer, contacting the substrate and defining an opening overlapping the lens layer; and
a filling part on the lens layer, spaced apart from the substrate and filling the opening.

9. The display device of claim 1, further comprising:
a polarization layer on the coating layer.

10. The display device of claim 1, further comprising:
a color filter layer between the light emitting element layer and the lens layer.

11. A method of manufacturing a display device, the method comprising:
forming a light emitting element layer including a plurality of light emitting elements in a display area on a mother substrate;
forming a pad part in a non-display area on the mother substrate;
forming a lens layer including a plurality of micro lenses on the light emitting element layer; and
forming a coating layer covering a side surface of the light emitting element layer and contacting the mother substrate on the lens layer.

12. The method of claim 11, further comprising:
attaching a release film to the non-display area on the mother substrate to cover the pad part before the forming the coating layer.

13. The method of claim 12, wherein the forming the coating layer includes:
forming a preliminary coating layer on the mother substrate to cover the lens layer and the release film;
cutting the preliminary coating layer;
removing the release film and the preliminary coating layer overlapping the release film; and
simultaneously cutting the preliminary coating layer and the mother substrate.

14. The method of claim 13, wherein
in the cutting of the preliminary coating layer, the preliminary coating layer is cut along one side surface of the display area adjacent to the release film, and
in the simultaneously cutting the preliminary coating layer and the mother substrate, the preliminary coating layer and the mother substrate are simultaneously cut along another side surface of the display area.

15. The method of claim 13, wherein the cutting the preliminary coating layer and the simultaneously cutting of the preliminary coating layer and the mother substrate are performed using a laser.

16. The method of claim 11, further comprising:
forming a low refractive index layer on the lens layer before the forming the coating layer.

17. The method of claim 11, wherein the forming the coating layer includes:
forming a sealing part covering the side surface of the light emitting element layer, contacting the mother substrate and defining an opening overlapping the lens layer; and
forming a filling part on the lens layer, spaced apart from the mother substrate and filling the opening.

18. The method of claim 13, further comprising:
forming a preliminary polarization layer on the preliminary coating layer before the cutting of the preliminary coating layer.

19. The method of claim 18, wherein the cutting the preliminary coating layer includes:
forming a polarization layer by cutting the preliminary polarization layer.

20. The method of claim 11, wherein the mother substrate is formed of a silicon wafer.
